(19) United States
(12) Patent Application Publication
(10) Pub. No.: US 2026/0351524 A1
(43) Pub. Date: Nov. 5, 2026

(54) SUBSTRATE ETCHING WITH AEROSTATIC BEARINGS

(71) Applicant: Lam Research Corporation, Fremont, CA (US)

(72) Inventors: Paul Konkola, West Linn, OR (US); Shaun Tyler Smith, Portland, OR (US); Yukinori Sakiyama, West Linn, OR (US); Karl Frederick Leeser, West Linn, OR (US)

(21) Appl. No.: 19/487,468

(22) PCT Filed: Jun. 5, 2024
(86) PCT No.: PCT/US2024/032557

§ 371 Date: Nov. 24, 2025

Related U.S. Application Data
(60) Provisional application No. 63/507,977, filed on Jun. 13, 2023.

(51) Int. Cl. H01J 37/32; H10P 50/24; H10P 72/78

(52) U.S. Cl. CPC H01J 37/32449; H01J 37/32568; H01J 37/32715; H10P 50/24; H10P 72/78; H01J 2237/2007; H01J 2237/202; H01J 2237/334

(57) ABSTRACT

Techniques and apparatus are provided for processing a semiconductor substrate. In some embodiments, such techniques may include: activating a first aerostatic bearing gas through a first surface of a first electrode subassembly; receiving the semiconductor substrate between the first surface of the first electrode subassembly and a second surface of a second electrode subassembly disposed opposite the first electrode subassembly; activating a second aerostatic bearing gas through the second surface; moving the second electrode subassembly to create stiffness between the semiconductor substrate and the first and second surfaces; and processing an edge portion of the semiconductor substrate using a plasma generated by the first and second electrode subassemblies.

### INCORPORATION BY REFERENCE

An Application Data Sheet is filed concurrently with this specification as part of the present application. Each application that the present application claims benefit of or priority to as identified in the concurrently filed Application Data Sheet is incorporated by reference herein in its entirety and for all purposes.

### BACKGROUND

Semiconductor manufacturing processes may create layers of films on a semiconductor substrate or wafer during fabrication, and may result in unwanted materials or metals on the substrate, particularly on the edge. Some processes such as edge bevel removal (EBR) can substantially process the edge of the wafer to remove the material. EBR can be performed by applying a reactive species (e.g., etchant) generated by a plasma source to remove material where desired, such as at the edge of the wafer. However, EBR is reaching its performance limits as requirements for etch rate, yield, and precision of the etching profile are increasing.

Background and contextual descriptions contained herein are provided solely for the purpose of generally presenting the context of the disclosure. Much of this disclosure presents work of the inventors, and simply because such work is described in the background section or presented as context elsewhere herein does not mean that it is admitted to be prior art.

### SUMMARY

In one aspect of the present disclosure, an apparatus configured to process a semiconductor substrate is disclosed. In some embodiments, the apparatus includes: a first subassembly comprising a first surface, a first electrode, and a first orifice; and a second subassembly comprising a second surface, a second electrode, and a second orifice, the second surface disposed opposite to the first surface to form a region sized to receive the semiconductor substrate between the first subassembly and the second subassembly; wherein: when in a first configuration, a first aerostatic bearing gas flows through the first orifice and a second aerostatic bearing gas flows through the second orifice to create a stiffness between the semiconductor substrate and the first surface and a substantially equal stiffness between the semiconductor substrate and the second surface; and the first and second electrodes are configured to generate plasma applied to an edge portion of the semiconductor substrate while the semiconductor substrate rotates about a central axis of the semiconductor substrate.

In another aspect of the present disclosure, a system configured to process a semiconductor substrate is disclosed. In some embodiments, the system includes: an upper electrode subassembly comprising an upper surface, an upper electrode, and an upper aerostatic bearing orifice; a lower electrode subassembly comprising a lower surface, a lower electrode, and a lower aerostatic bearing orifice, the lower surface disposed opposite to the upper surface to form a region sized to receive the semiconductor substrate between the upper electrode subassembly and the lower electrode subassembly; a stage assembly having a plurality of degrees of freedom and configured to move the semiconductor substrate to the region via at least a first degree of freedom; wherein: when in a first configuration, an upper aerostatic bearing gas flows through the upper aerostatic bearing orifice and a lower aerostatic bearing gas flows through the lower aerostatic bearing orifice to create a stiffness between the semiconductor substrate and the upper surface and a stiffness between the semiconductor substrate and the lower surface; and the upper and lower electrodes are configured to generate plasma applied to an edge portion of the semiconductor substrate while the stage assembly implements a second degree of freedom on the semiconductor substrate.

In another aspect of the present disclosure, a method of processing a semiconductor substrate is disclosed. In some embodiments, the method includes: activating a first aerostatic bearing gas through a first surface of a first electrode subassembly; subsequent to activating the first aerostatic bearing gas, receiving the semiconductor substrate between the first surface of the first electrode subassembly and a second surface of a second electrode subassembly disposed opposite the first electrode subassembly; subsequent to receiving the semiconductor substrate, activating a second aerostatic bearing gas through the second surface; subsequent to activating the second aerostatic bearing gas, moving the second electrode subassembly to create stiffness between the semiconductor substrate and the first and second surfaces; and processing an edge portion of the semiconductor substrate using a plasma generated by the first and second electrode subassemblies.

These and other features of the disclosed embodiments will be described in detail below with reference to the associated drawings.

### BRIEF DESCRIPTION OF DRAWINGS

FIGS. 1A and 1B are simplified diagrams of hardware configurations for material removal from a semiconductor substrate using a plasma source, according to some embodiments.

FIG. 2 is an overview diagram of a hardware configuration for a material removal system configured to provide a pressurized jet of plasma toward a of a semiconductor substrate, according to some embodiments.

FIG. 2A is a cross-sectional view of the overview diagram of the hardware configuration for the material removal system of FIG. 2.

FIGS. 2B and 2C are cross-sectional views of portions of the material removal system of FIG. 2, showing components of the system and a confinement ledge useful for implementing the system.

FIGS. 2D and 2E illustrate indirect and direct plasma generation that may be used with the material removal system described herein.

FIG. 2F illustrates three factors that may be involved in processing a wafer edge using a plasma source, including radical generation, transportation, and surface reaction.

FIG. 2G a closer view of hardware configuration of material removal system, according to some embodiments.

FIG. 2H is a cross-sectional views of the plasma source with a confinement ledge.

FIG. 2I is a cross-sectional views of the plasma source with multiple confinement ledges.

FIGS. 2J-2M illustrate cross-sectional views of hardware components configured to provide aerostatic bearing while processing (e.g., etching an edge of) the semiconductor substrate, according to some embodiments.

FIG. 3 is a depiction of an edge of a semiconductor substrate resulting from implementing the material removal system disclosed herein.

FIGS. 4A-4D illustrate steps for loading a semiconductor substrate for processing.

FIG. 5 is a flow diagram illustrating a method of processing a semiconductor substrate, according to some embodiments.

FIG. 6 is a flow diagram illustrating another method of processing a semiconductor substrate, according to some embodiments

FIG. 7 illustrates a simplified block diagram of a system or apparatus as described herein.

### DETAILED DESCRIPTION

The following terms are used throughout the present specification:

A “semiconductor device fabrication operation” as used herein is an operation performed during fabrication of semiconductor devices. As referred to herein, such a fabrication operation is sometimes simply referred to as a “process” or as “processing.” Examples of processing include deposition of a material on a substrate, selectively etching material from a substrate, and ashing of photoresist on a substrate. Typically, the overall fabrication process includes multiple semiconductor device fabrication operations, each performed in its own semiconductor fabrication tool such as a plasma reactor, an electroplating cell, a chemical mechanical planarization tool, a wet etch tool, and the like. Categories of semiconductor device fabrication operations include subtractive processes, such as etch processes and planarization processes, and material additive processes, such as deposition processes (e.g., physical vapor deposition, chemical vapor deposition, atomic layer deposition, electrochemical deposition, electroless deposition). In the context of etch processes, a substrate etch process includes processes that etch a mask layer or, more generally, processes that etch any layer of material previously deposited on and/or otherwise residing on a substrate surface. Such an etch process may etch a stack of layers in the substrate.

The terms “semiconductor wafer,” “wafer,” “substrate,” “wafer substrate” and “partially fabricated integrated circuit” may be used interchangeably. Those of ordinary skill in the art understand that the term “partially fabricated integrated circuit” can refer to a semiconductor wafer during any of many stages of integrated circuit fabrication thereon. A wafer or substrate used in the semiconductor device industry typically has a diameter of 200 mm, or 300 mm, or 450 mm. Examples of semiconductor substrate materials include silicon (Si), gallium arsenide (GaAs), and silicon germanium (SiGe).

Besides semiconductor wafers, other workpieces that may take advantage of the disclosed embodiments include various articles such as magnetic recording media, magnetic recording sensors, mirrors, optical elements, display devices or components such as backplanes for pixelated display devices, flat-panel displays, micro-mechanical devices and the like. The workpiece may be of various shapes, sizes, and materials.

This disclosure generally relates to processing a semiconductor substrate to, e.g., remove unwanted materials from a portion of the substrate such as an edge of the substrate. Some implementations involve usage of at least one aerostatic bearing and a spinning substrate to process the edge with a plasma jet. An enhanced approach with a high etch rate, improved etching profile (e.g., short transition from etched edge to unprocessed film) which remains cost effective and reduces system footprint is desirable.

Such an enhanced approach, according to some embodiments of the present disclosure, may leverage so-called atmospheric pressure plasma jet (APPJ) technology for edge bevel removal (EBR) technology in recipe-controlled etching to remove material (e.g., one or more existing layers) from portions of a semiconductor substrate, which in some aspects may involve operating one or more nozzles at atmospheric conditions to provide a pressurized jet of plasma radicals toward the substrate.

Since APPJ may be used to deposit material using certain configurations, the present disclosure is not necessarily limited to etching. That is, the material removal system 100 or 200 may be used for deposition despite its naming convention, and the functionalities thereof are not limited to material removal. For example, precursors may be selected for chemical vapor deposition (PECVD) or plasma enhanced atomic layer deposition (PEALD) as mentioned elsewhere below. However, the following description will primarily focus on material removal using etching for enhanced EBR.

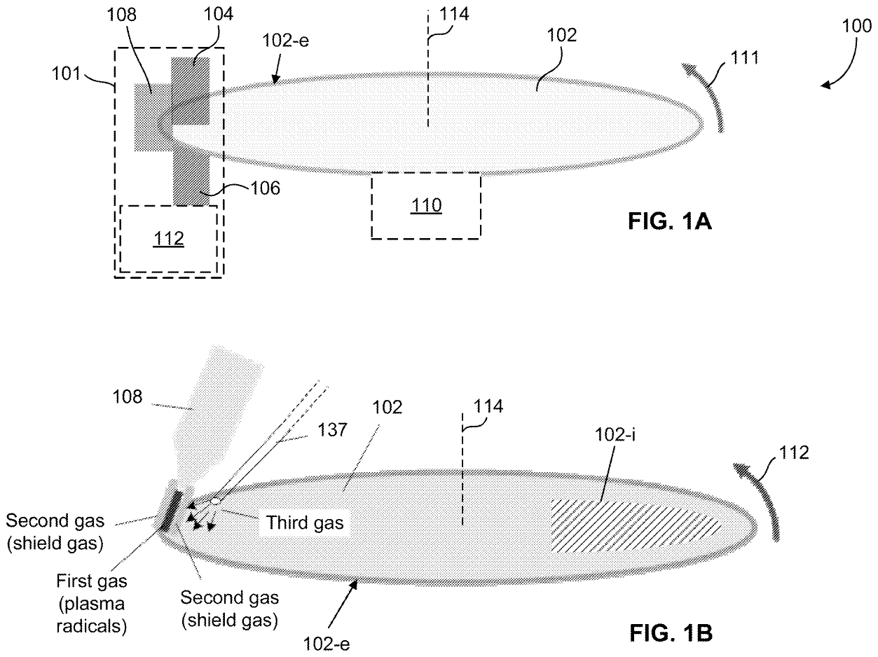

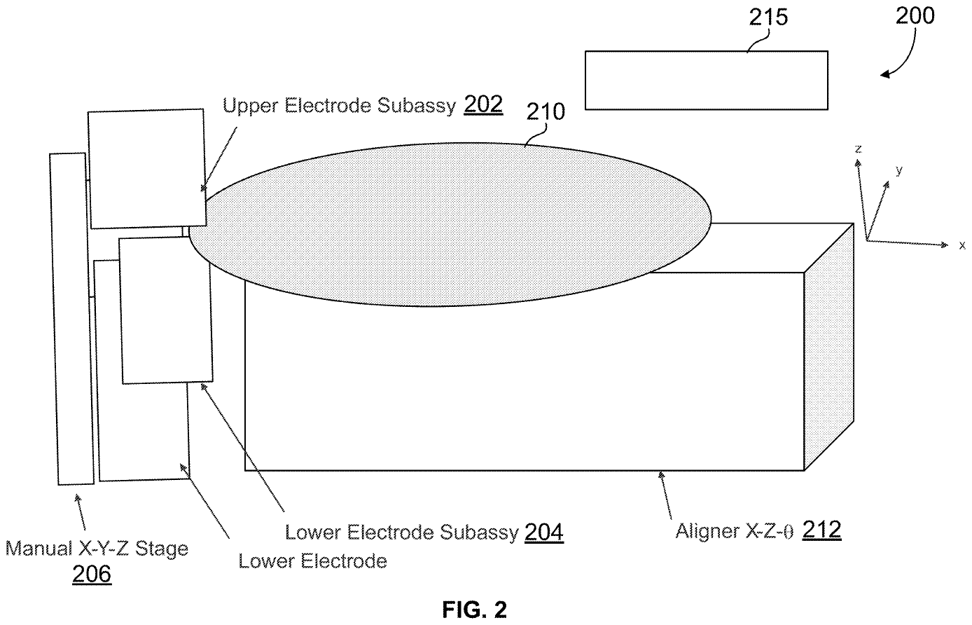

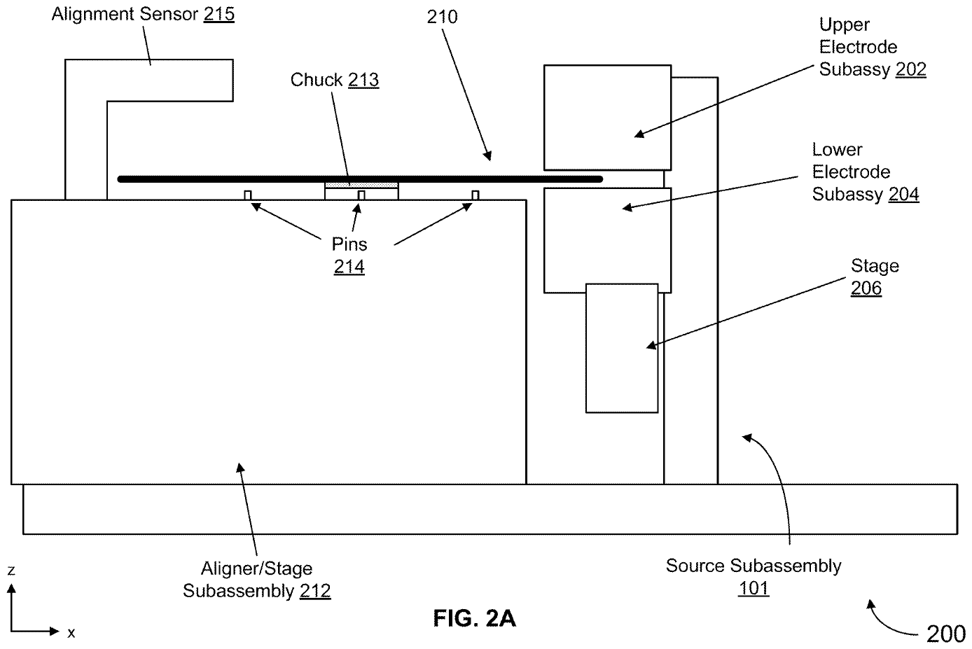

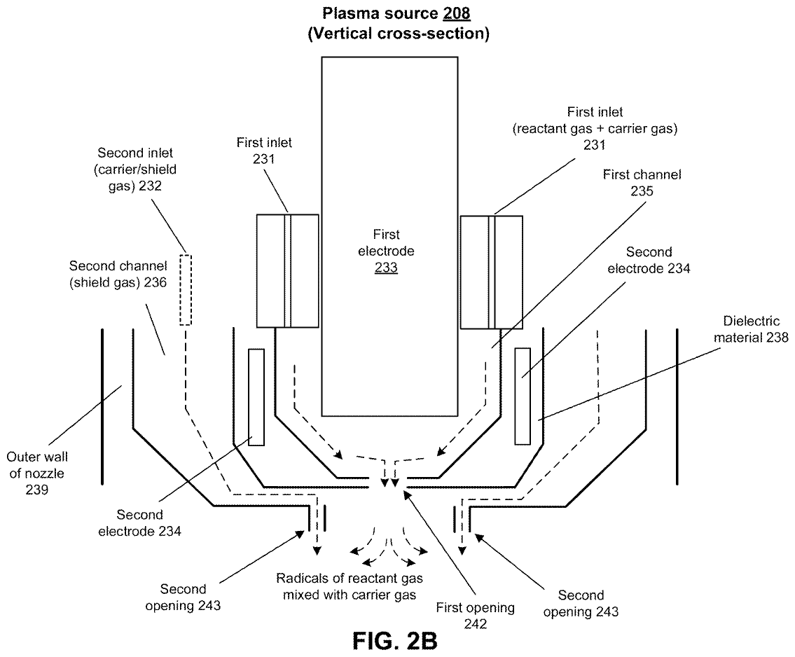

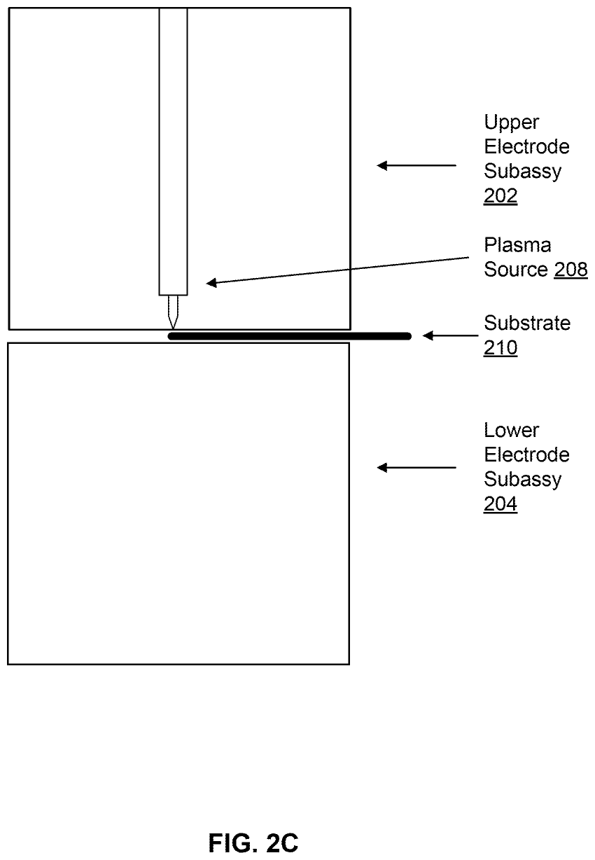

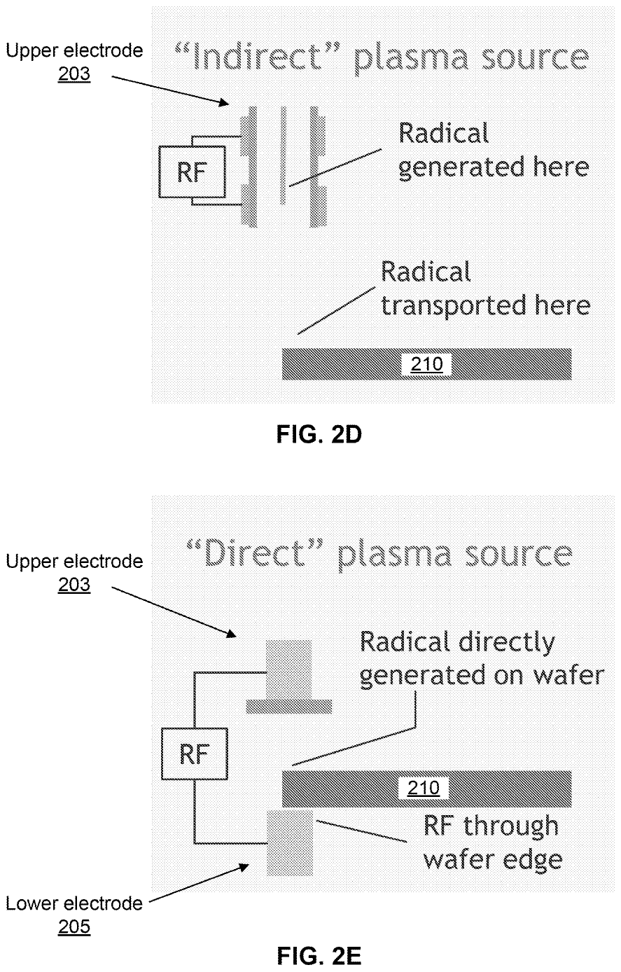

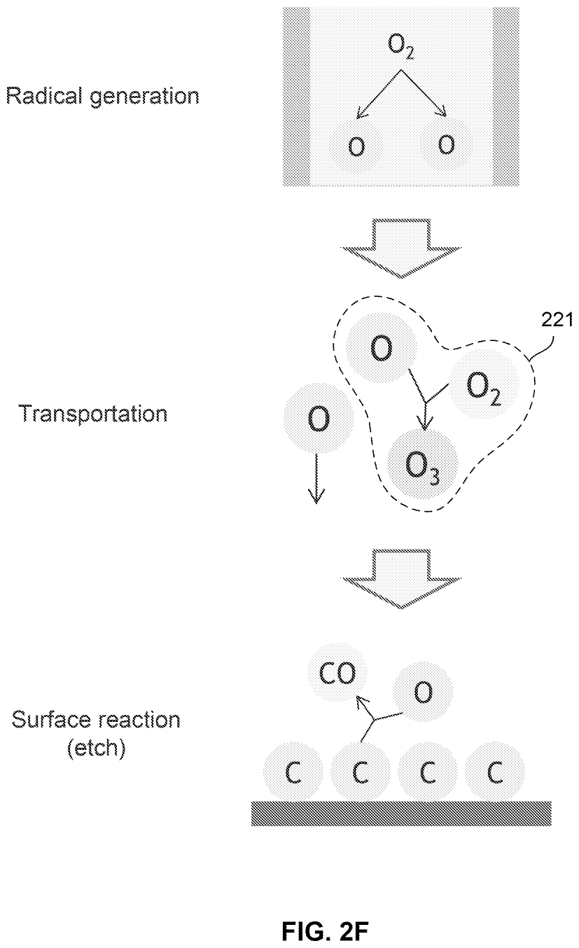

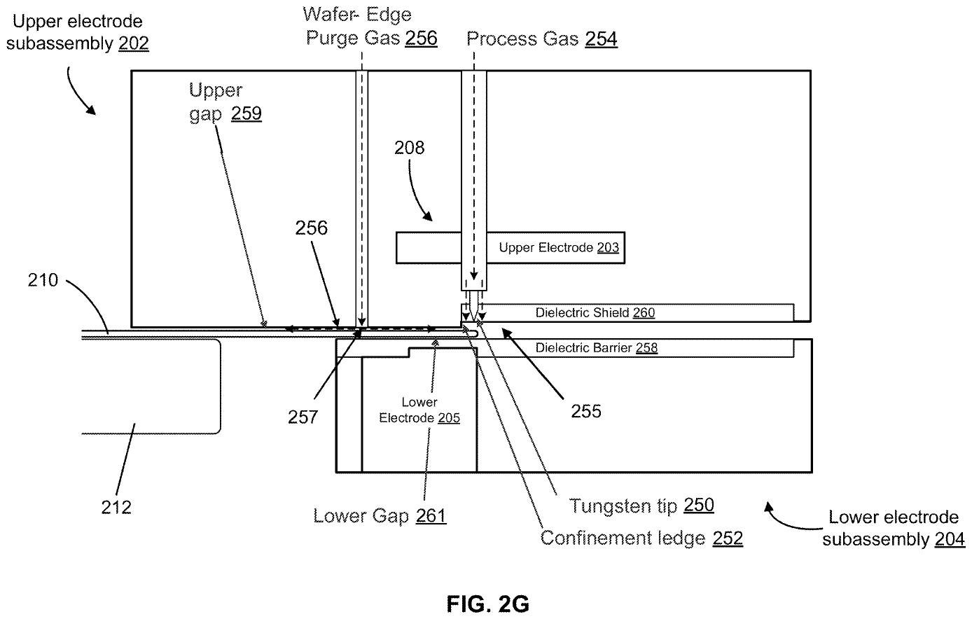

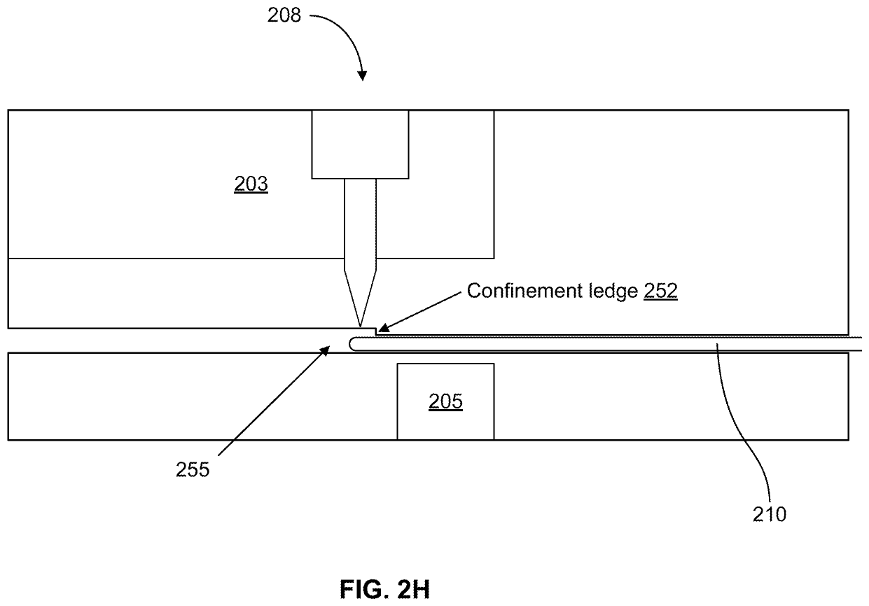

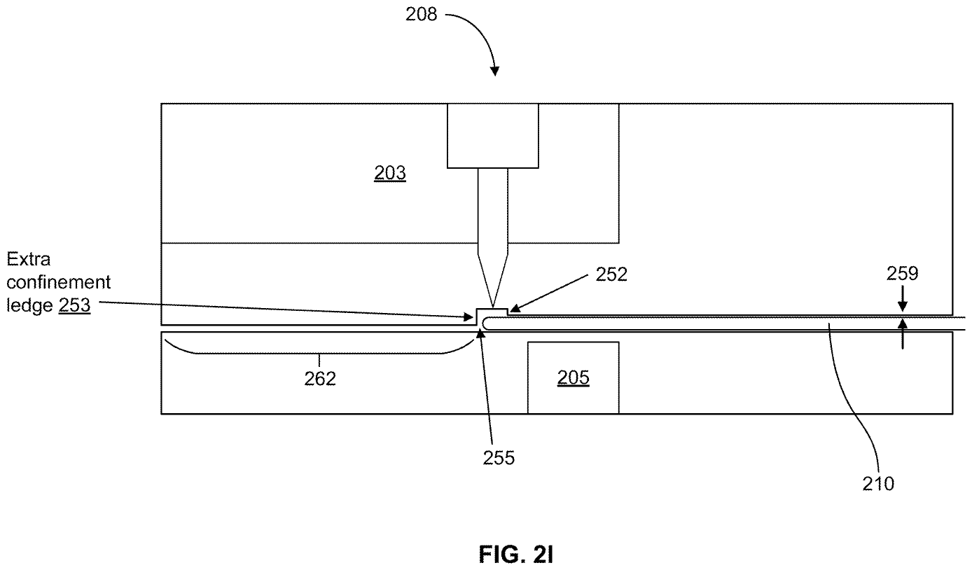

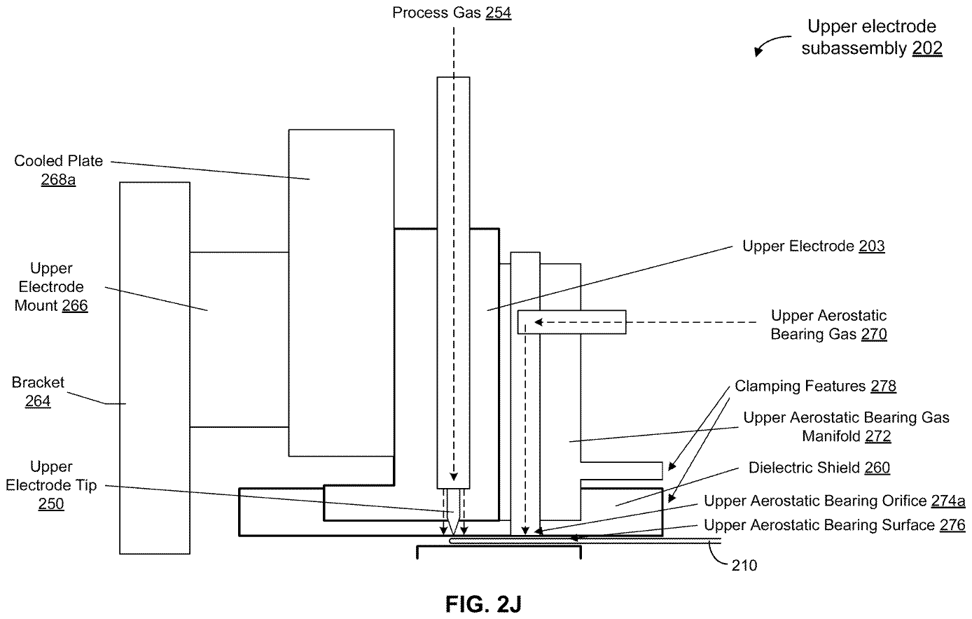

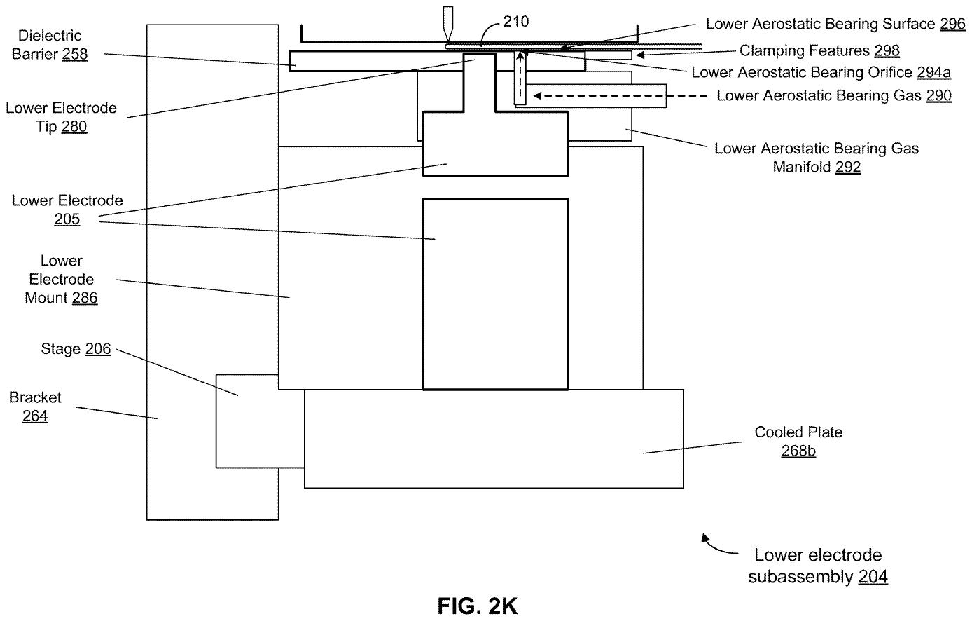

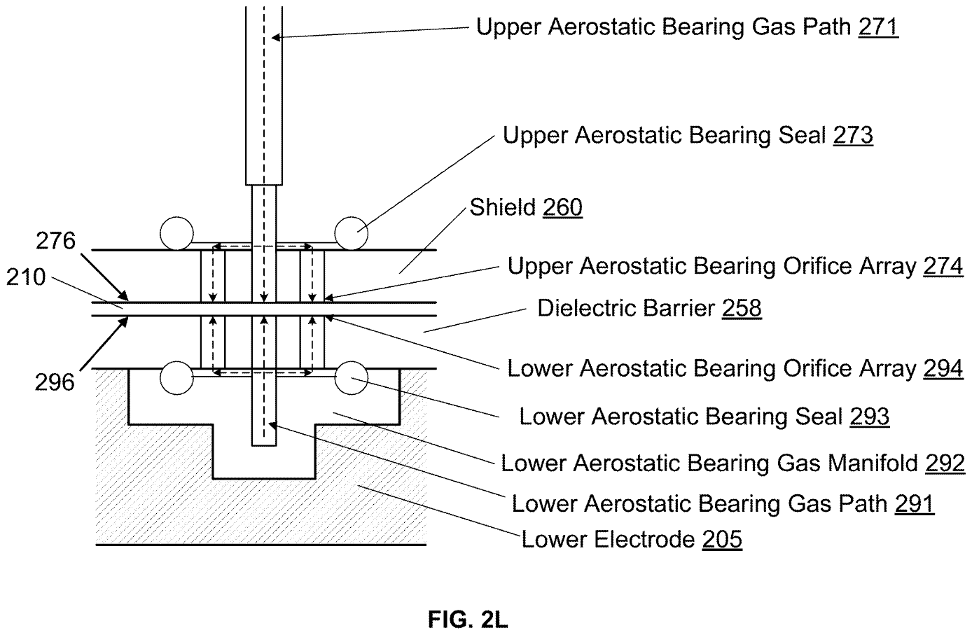

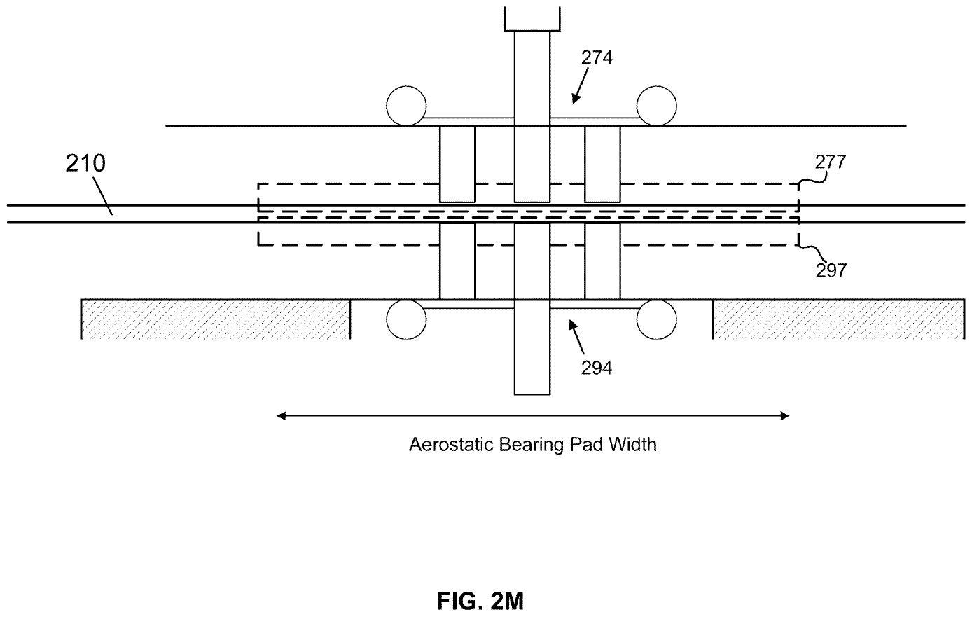

The details of the components of a system using APPJ for EBR will be discussed with reference to FIGS. 1A through 2M. Such a system may be configured to emit plasma radicals that processes a specific location of a semiconductor substrate, e.g., to remove materials at the substrate edge. Using the hardware of such a system, a wafer may be spun on an aligner hardware and through a controlled plasma emitting region, where a plasma source (e.g., a plasma jet) may be configured to etch (or deposit in some configurations) material on a wafer, including on a front side, edge, and/or a back side of the wafer. More particularly, plasma chemistry may etch the region near the wafer edge (or other portions of the wafer). In some embodiments of the present disclosure, rather than using a single jet, an arc-shaped jet that may consist of a single jet region or an array of jets may be employed. In some implementations, such an array may be as simple as many jets distributed across the wafer radius. As alluded to above, alternatively, rather than etch, a suitable choice of plasma feed gases can induce a plasma enhanced chemical vapor deposition of material.

### Edge Bevel Removal (EBR) Using Atmospheric Pressure Plasma Jet (APPJ)

FIG. 1A illustrates an example view of plasma radicals applied to a semiconductor substrate 102, according to some implementations of a material removal system 100 described herein. In some embodiments, the system 100 may include a source subassembly (or subassemblies) 101 that includes an upper subassembly 104, a lower subassembly 106, and a plasma source 108. As noted elsewhere, the plasma source 108 may include at least one plasma jet or at least one nozzle. In some embodiments, the upper subassembly 104 may include an electrode or an electrode subassembly. In some embodiments, the upper subassembly 104 may provide aerostatic bearing or aerodynamic bearing. In some embodiments, the lower subassembly 106 may include an electrode or an electrode subassembly separate from that of the upper subassembly 104. In some embodiments, the lower subassembly 106 may provide aerostatic bearing and aerodynamic bearing load capacity. Aerostatic bearings use a layer of pressurized gas to provide a low friction load-bearing interface between surfaces. An aerodynamic bearing may form load capacity via the relative velocity of the moving gas between static and moving surfaces (e.g., between a surface of a subassembly and a surface of a spinning substrate). The aerodynamic bearing capacity is beneficial for enabling lower consumption of gas and may allow some operations to perform with no required flow of externally supplied gas.

In some embodiments, the semiconductor substrate 102 may be positioned or placed at a plasma emitting region, between the upper subassembly 104 and the lower subassembly 106, where the components in conjunction (including the plasma source 108) may substantially process an edge 102-e of the semiconductor substrate 102 as the substrate rotates along a selected direction 111 relative to the upper subassembly 104 and the lower subassembly 106, e.g., about a central axis 114 of the substrate. More specifically, in some configurations, the plasma source 108 may be substantially confined to the edge of the semiconductor substrate 102 by placement of the substrate edge 102-e proximate to a tip associated with a nozzle or jet of the plasma source 108. The plasma source 108 may be positioned along the upper subassembly 104 (e.g., the tip of the plasma source 108 may be flush with a surface of upper subassembly 104). In some embodiments, a portion of the semiconductor substrate 102 in proximity to the plasma may be sandwiched between one or more surfaces of the upper and lower subassemblies 104, 106 for precision gap control. For example, the upper subassembly 104 may include an opening for aerostatic bearing gas to flow onto the upper surface of semiconductor substrate 102. Said proximity may be at the micron level (e.g., range of microns to tens of microns, or under about 100 microns). Advantageously, the resulting micron-level gapping between semiconductor substrate 102 and aerostatic bearing surfaces provides benefits for plasma confinement (e.g., away from inner portions or center of the substrate), edge purge (e.g., removing residues from etched portions), stability of rotating the semiconductor substrate 102, and efficient processing. Advantageously, the plasma source 108 may be enabled to process the edge of the wafer with a short transition from an etched edge to unprocessed film across a defined distance. The edge of the processed semiconductor substrate 102 may have a substantially vertical cut with a sharp transition in thickness. A vertical cut may help prevent a flow of plasma radicals toward the inner portion or center of the substrate.

During processing (e.g., etching), the semiconductor substrate 102 may be spun in the selected direction 111 (e.g., counterclockwise or clockwise) about the axis 114 while secured by other hardware such as an aligner hardware 110. In some cases, the aligner hardware 110 may be configured to translate, traverse, and/or spin (e.g., actuate in X-Y or R-θ-Z directions). In some cases, the aligner hardware 110 may be configured to control another apparatus and cause the other apparatus to translate, traverse, and/or spin. The semiconductor substrate 102 may be secured via the backside, e.g., by vacuum chucking (or in some cases, electrostatic chucking or clamping) with the aligner hardware 110 to secure the semiconductor substrate 102. In some cases, the source subassembly 101 may have a stage 112 coupled thereto for actuation of at least portions of the source subassembly 101 (e.g., in X-Y-Z directions).

In some implementations, the aligner hardware 110 may actuate (e.g., move in X-Y-Z direction) and/or adjust the spin rate, while optionally, radio frequency (RF) power associated with the plasma source 108 may be modulated so as to stop or start etching. An example range of frequency for the RF power may be between about 10 kilohertz (kHz) to about 100 megahertz (MHz). The sharp transition may increase the area on a wafer that yields working die while the specified diameter ensures material removal where desired. Additional details regarding the material removal using the components of subassemblies 104, 106 (e.g., electrodes) and plasma source 108 will be discussed in greater detail below with respect to FIGS. 2-2I.

FIG. 1B illustrates an example view of plasma radicals with shield gas directed toward an edge 102-e of a semiconductor substrate 102, according to some implementations of the system 100 (e.g., of FIG. 1) described herein. In this configuration, a plasma source 108 may be configured to emit a first gas (e.g., plasma radicals) and a second gas (e.g., shield gas) through respective first and second openings of the plasma source 108. In some implementations, the first gas and the second gas may be emitted from openings other than that of the plasma source 108. The second gas may act as a shield to enable a focused application of the radicals to a specific location (e.g., the edge) of the semiconductor substrate 102. Shield gas may also prevent the plasma radicals from dispersing or recombining with the surrounding air (e.g., as illustrated with respect to FIG. 2F (recombination 221)), enabling focused application of the plasma radicals to the substrate edge 102-e. In the illustrated example operation, as the substrate 102 rotates about an axis 114, different portions of the substrate edge 102-e may be become exposed to plasma radicals.

In some operations, the system configuration may be used to deposit a layer on one or more portions of the substrate 102 (e.g., on the front side) as it rotates, e.g., on the inner portion 102-i or the substrate edge 102-e.

Generally speaking, plasma radicals reaching portions other than the substrate edge 102-e (such as inner portion 102-i) is undesirable, as deposited film or components should remain undisturbed. Hence, in some implementations, the plasma source 108 (e.g., a nozzle thereof) may be positioned or angled toward or away from inner portion 102-i of the substrate 102. The illustrated example in FIG. 1B shows that the nozzle is pointed away from the center of the substrate 102, which may assist with removal of the edge material and prevention of radical accumulation in other parts of the substrate 102. For further assistance, in some implementations, a third gas such as a purge gas and/or aerostatic bearing gas received via a third channel 137 defined adjacent to or otherwise proximate the plasma source 108 (e.g., at another portion of the upper subassembly 104) may be supplied through a third opening proximate the surface of the substrate 102. In some implementations, however, the third channel 137 may be part of (e.g., within the same housing as) the plasma source 108. The third gas may be supplied with sufficient force to keep the plasma radicals directed away from the center of the substrate 102 and toward the substrate edge 102-e and to sufficiently expose the substrate edge 102-e to the plasma radicals. In some cases, the purge gas and aerostatic bearing gas may be supplied through separate third and fourth openings. Further inlets and openings may be present in other configurations.

Advantageously, when used with a relatively high-pressure gas (e.g., at about atmospheric pressure or a specified fraction thereof) compared to traditional approaches, the material removal system 100 can offer higher reaction product density than is possible with lower-pressure processes. The disclosed concepts offer the advantages and benefits of direct-write capability for high process tunability, very high throughput due to very high etch (or deposition) rate, much lower cost, the ability to easily integrate with etch (or deposition) tools, and if pursued as a standalone implementation, a much lower product footprint. The topology shown in FIGS. 1A and 1B may thereby offer substantial cost savings in hardware compared to current technology based in part on smaller parts volume.

Another advantage of using APPJ in conjunction with EBR is that, although the wafer rotation may be fast (a rate of rotation of, e.g., 60-120 rotations per minute), modulating the RF power to plasma jets associated with the plasma source 108 can be done much faster. Beside control of plasma generation and transport, synchronization of the power and substrate angle or position can produce regions of various film properties to tune the net etch profile as desired, e.g., using on/off or high/low RF power modulation.

FIG. 2 illustrates an overview diagram of a hardware configuration for a material removal system 200, according to some embodiments. In some embodiments, the system 200 may include an upper electrode subassembly 202, a lower electrode subassembly 204, a plasma source (not shown), a stage 206 configured for actuation of the upper and/or lower electrode subassemblies (e.g., in X-Y-Z directions), and an aligner 212 configured for actuation of a semiconductor substrate 210 (e.g., in X-Y or R-θ-Z). In some implementations, the upper subassembly 104 of FIG. 1 may correspond to or include the upper electrode subassembly 202, and the lower subassembly 106 of FIG. 1 may correspond to or include the lower electrode subassembly 204. The system 200 as shown in FIG. 2 may be agnostic to aerostatic bearing depending on the implementation, however.

In some embodiments, a plasma source may be disposed with (e.g., adjacent, within, or proximate) the upper electrode subassembly 202. In some embodiments, a plasma source may (additionally or alternatively) be disposed with the lower electrode subassembly 204. The plasma source may generate chemically reactive species, e.g., an etchant, which may be provided to portions (e.g., edges or other locations) of the semiconductor substrate 210 in a controlled manner as the semiconductor substrate 210 spins. The spatial distribution of plasma (i.e., an etching profile) may controlled by the configuration of electrodes and gas flow. For example, RF power modulation of upper electrode subassembly 202 and/or lower electrode subassembly 204 may be controlled. Further, flow of first, second and/or third gases as discussed with respect to FIG. 1B may be controlled. Control of these parameters relating to electrodes and gas flow may result in the desired on-wafer etching profile.

By way of background, plasmas may be generated by applying an RF field (e.g., via one or more electrodes) to a gas. The plasma generates reactive species. Reactive species may include electrons, ions, radicals, and neutral species. Ionization of the gas by the RF field ignites the plasma, creating free electrons in the plasma discharge region (e.g., within the plasma source). These electrons are accelerated by the RF field and may collide with gas phase reactant molecules. Collision of these electrons with reactant molecules may form radical species that participate in an etching process or a deposition process.

As the semiconductor substrate 210 spins (e.g., via the aligner 212) while positioned between the upper and/or lower electrode subassemblies 202, 204, portions (e.g., edges) of the substrate may be exposed to etchant generated at the plasma source, whereby plasma chemistry and/or modulation of RF power applied to the upper and/or lower electrode subassemblies 202, 204 may etch the portions of the substrate 210. In some instances, the inner part of the semiconductor substrate 210, where materials should not be removed, may be protected by a solid object (e.g., a cover) to prevent diffusion of the etchant into the inner area of the wafer. One example of such a solid object may be a confinement ledge as will be discussed with respect to FIGS. 2H and 2I. Thus, at least in part based on physical obstructions (and/or purge gas), materials may be removed only at the wafer edge even if plasma-generated etchant fills the process volume.

However, as noted before, industry requirements for etch rate are increasing, and the necessary precision of the etching profile is becoming narrower. To account for this, positioning of the semiconductor substrate 210 relative to a lower surface of the upper electrode subassembly 202 and relative to an upper surface of the lower electrode subassembly 204 may be precisely controlled. More specifically, the gap between the two subassemblies may be defined. In some cases, this requires highly skilled operators or engineers and takes a long period of time to optimize the hardware configuration. The solid object or cover may also need to be re-designed to change the etching profile. Once the hardware is set up and the chamber is closed, it becomes difficult to tune the etching profile and etching width without opening the chamber.

Therefore, the present disclosure may utilize the fact that diffusivity of gas is smaller at higher pressures. For instance, at a higher pressure of gas, such as atmospheric pressure, the diffusivity of gas is 760 times lower than a typical lower-pressure operating condition. Thus, etching profile may be adjusted by controlling a gas curtain, not mechanical hardware. Additionally, a point source may be chosen with a wafer spinner over a ring-shaped source with a fixed pedestal. This may reduce or minimize non-uniform etching around the wafer bevel because wafer rotation smooths out spatial and temporal plasma fluctuation. Moreover, atmospheric-pressure EBR does not require vacuum pumps, which may reduce the mechanical footprint and the cost. Hence, configurations of the system 200 may advantageously enable etching materials to be applied only at the wafer edge without a vacuum system, which may reduce the cost and the system footprint.

However, it will be recognized that the system 200 may also be configured to apply etchants at different portions of a wafer (e.g., other than the edge) for a desired etching profile for other applications, such as compensating for existing wafer bow. For instance, the gap between electrode subassemblies 202, 204 may be extended and/or the protective solid object (e.g., cover) may be absent or placed such that the aligner 212 may move the wafer “deeper” into the assemblies, allowing etching at portions other than the edges (e.g., inner portion 102-i as shown in FIG. 1B).

FIG. 2A illustrates a cross-sectional overview diagram of a hardware configuration for a material removal system 200, according to some embodiments. In some embodiments, upper electrode subassembly 202, lower electrode subassembly 204, and stage 206 may be configured to receive a semiconductor substrate 210 that is actuated via an aligner 212 may be used as discussed above with respect to FIG. 2. In some embodiments, the upper electrode subassembly 202, lower electrode subassembly 204, and stage 206 may be part of a source subassembly 101 as described with respect to FIG. 1A. In some embodiments, the aligner 212 may include a chuck 213, one or more pins 214, and/or an alignment sensor 215.

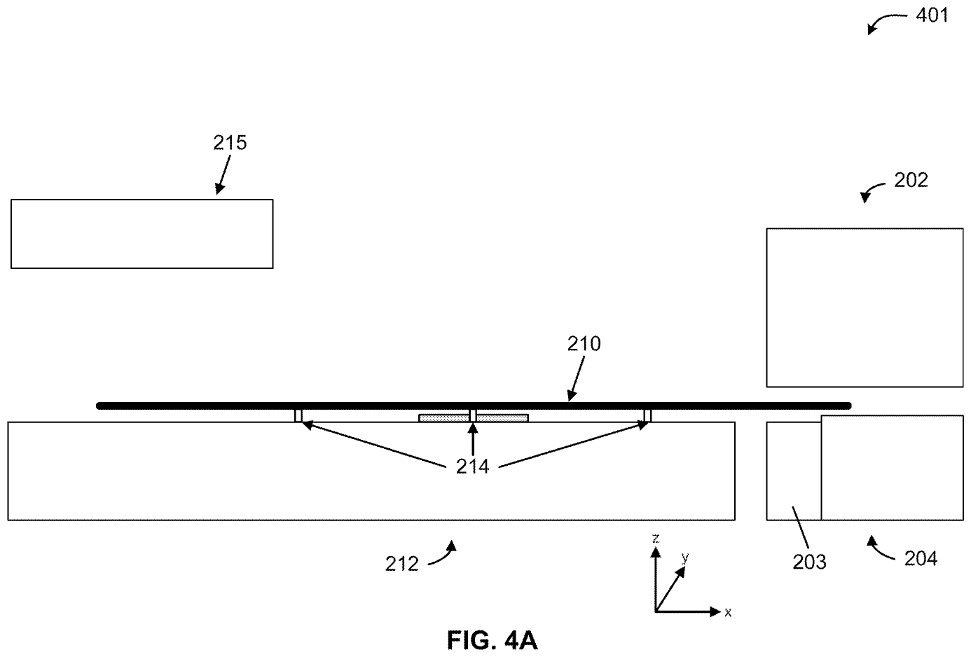

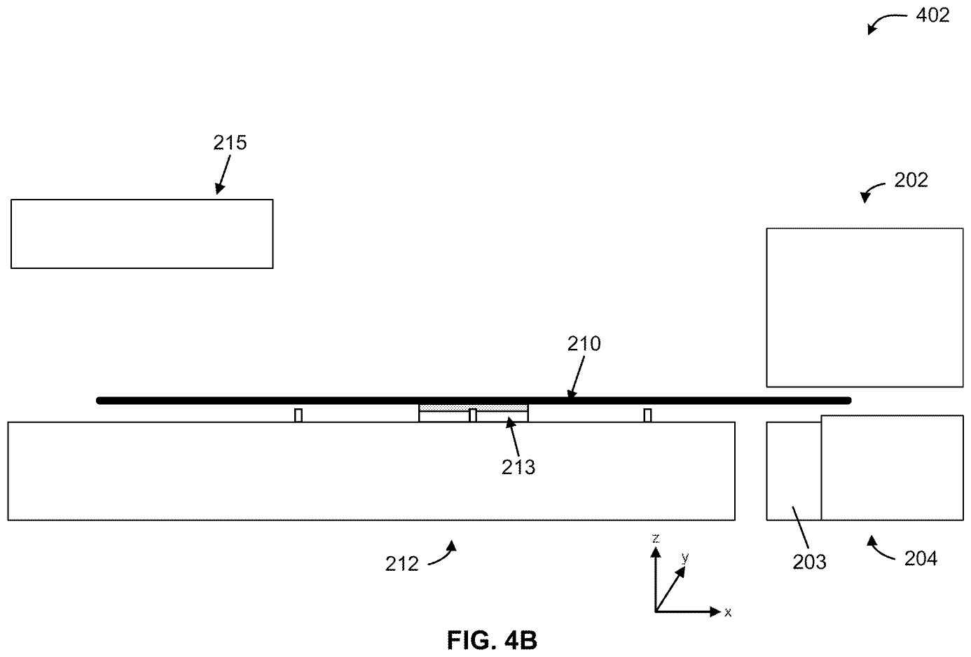

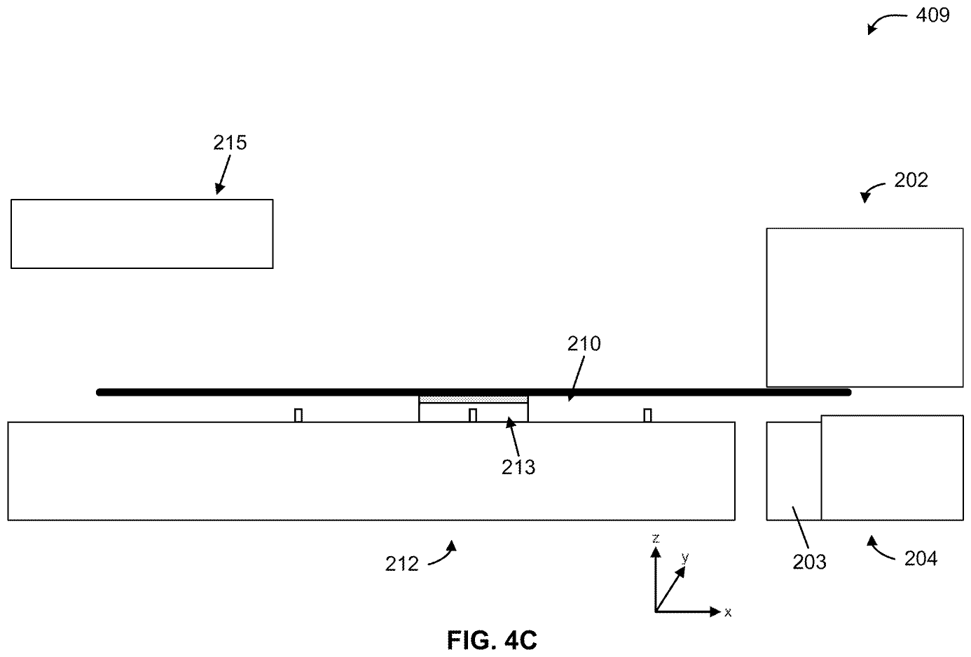

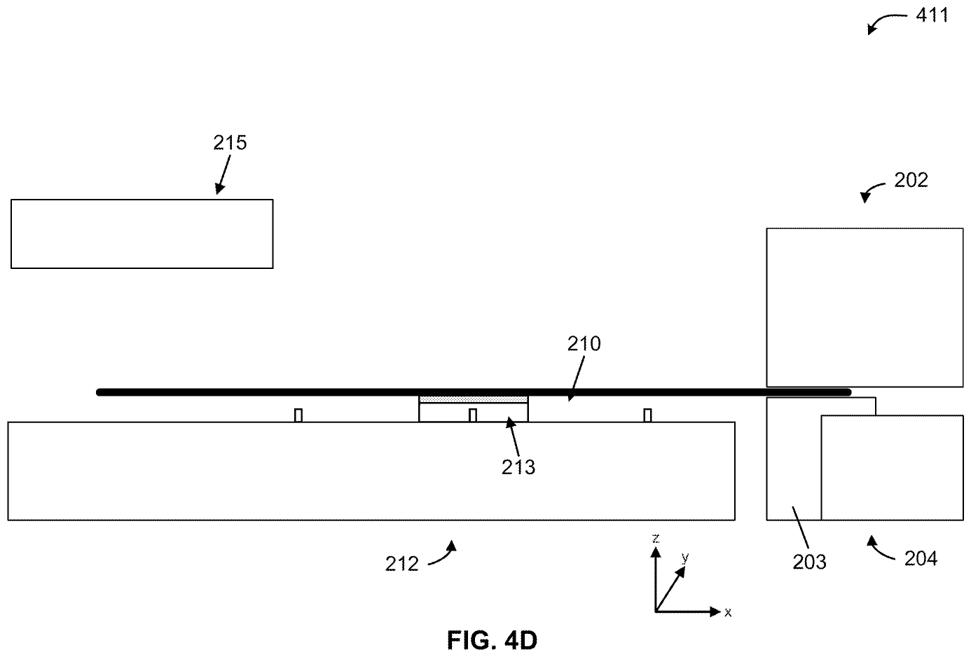

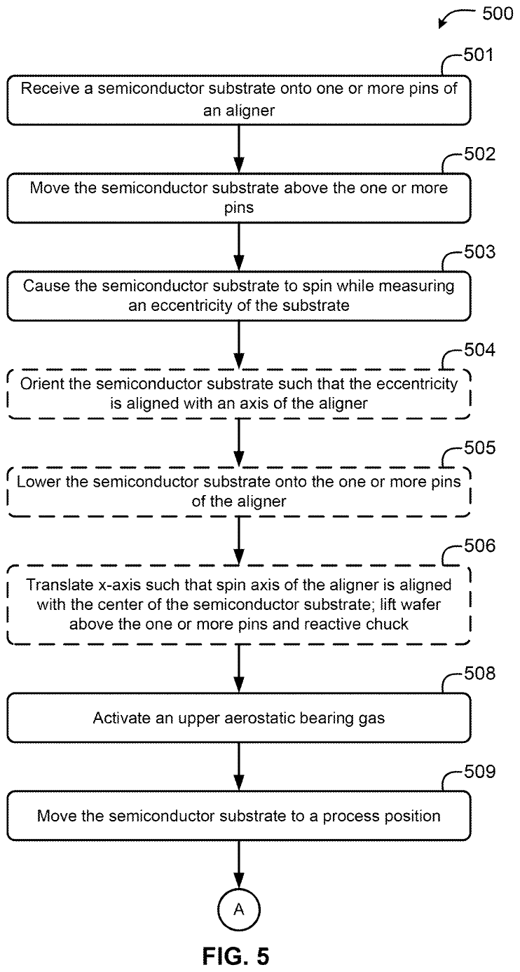

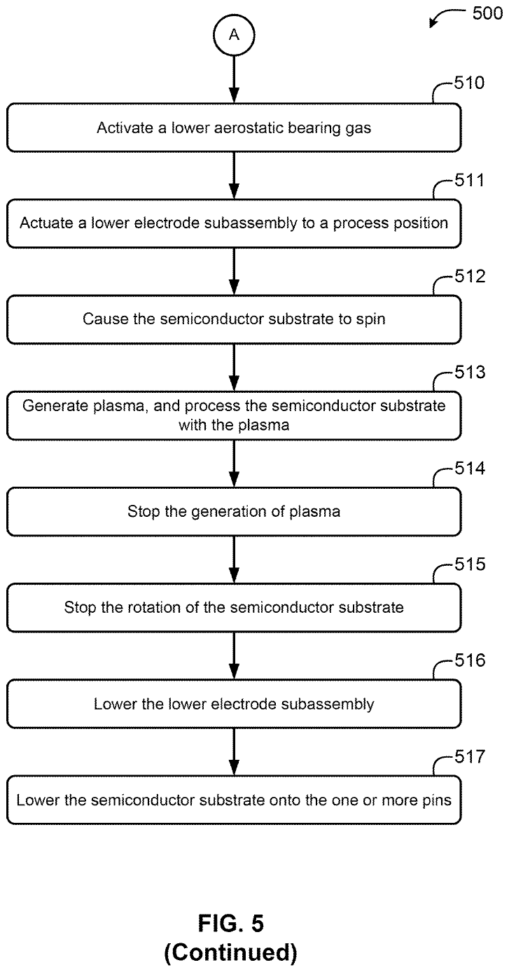

The aligner 212 may include various components that are configured to securely hold and actuate the semiconductor substrate 210 to, e.g., raise, lower, insert into source subassembly 101 (e.g., between the upper and lower electrode subassemblies 202, 204). While specifics of this insertion approach will be described in more detail with respect to FIGS. 4A-4D and 5, an overview of the components is now provided. In some implementations, the aligner 212 may be used to adjust the position of the substrate 210 on the chuck 213 such that the wafer spins with minimized eccentricity. The substrate 210 may also be servoed or actuated (e.g., in x- or y-direction toward or away in an orthogonal direction to upper and lower electrode subassemblies 202, 204) as the substrate 210 spins using the measured eccentricity to minimize the edge motion under, e.g., a plasma jet of the upper electrode assembly substrate 202.

Those of ordinary skill in the art will recognize various configurations of securing the substrate 210 with respect to the chuck 213. In some embodiments, the chuck may be a vacuum chuck 213. That is, the aligner 212 may securely hold the substrate 210 with sufficient holding force using suction of the vacuum chuck. Vacuum chucks are simple, convenient, and cost-effective to implement. In fact, vacuum chucking may be especially appropriate for processing occurring at atmospheric pressure according to the present disclosure, since, in a vacuum chamber where pressure would already be dramatically lower than atmospheric, there would not be an ability to vacuum chuck the substrate 210. In a vacuum environment, or in the atmospheric environment, other types of chucking may be used, such as below.

In alternate embodiments, the chuck 213 may be an electrostatic chuck (ESC), which may securely hold the substrate 210 using electrostatic force. In some cases, such an ESC may be a bipolar ESC having a pair of complementary and coplanar clamping electrodes (which may be embedded within a pedestal structure) which generate the electrostatic force. In some cases, the ESC may be a monopolar ESC having one clamping electrode, where the one electrode may have a voltage applied thereto and an opposite charge may be induced in the substrate 210 using, e.g., an opposing electrode above the substrate 210 (or, in certain implementations, a plasma generated above the substrate 210, e.g., if within a process chamber).

In some embodiments, the chuck may be configured to move in multiple degrees of freedom. One example of a degree of freedom is translation. Another example is rotation. The chuck may be configured to translate along an x-axis, a y-axis and/or a z-axis, e.g., using an actuator, causing the substrate 210 to move in the corresponding direction(s). In addition, the chuck may be configured to rotate with respect to the z-axis, causing the secured substrate 210 to rotate at the same rate of rotation (e.g., 60-120 rotations per minute, e.g., 100 rotations per minute). In some implementations, the chuck may be secured to a separate stage (or separate actuator), e.g., a stage (not shown) that is configured to translate (along the x-axis, the y-axis and/or the z-axis) and/or spin or rotate (with respect to the z-axis), or cause the chuck to translate, spin and/or rotate. Spin about the z-axis may allow the nozzle to cover the entirety of the circumference of the substrate 210 (e.g., along its outer edge), and with control of the state of the nozzle (high/low or on/off), various etching patterns can be formed. In some implementations, the nozzle housing or the nozzle may be configured to rotate or tilt or angle about the x and/or y-axes so that the nozzle can cover a greater portion of the substrate 210 when the substrate 210 is positioned over the nozzle. In some implementations, the position of the nozzle may be varied with respect to the nozzle housing. For example, the nozzle may be repositioned along the x-axis, y-axis, z-axis, radial (r) direction, and/or an angular (θ) direction. Angular repositioning may cause tilting of the nozzle with respect to the nozzle housing, but the nozzle housing may remain in the same angular position or tilt.

In some embodiments, the pins 214 may be ceramic, metallic, or elastomer pads or raised platforms configured to hold the semiconductor substrate 210 when the substrate is not being secured by the chuck 213. For example, the semiconductor substrate 210 may be placed onto the pins 214. In some cases, the substrate may be placed in a specific position (e.g., relative to the chuck), or orientation or direction, according to a wafer notch or marker on the substrate and/or position sensing by the alignment sensor 215. Proper placement of the semiconductor substrate 210 on the pins 214 may allow the chuck 213 to secure the semiconductor substrate 210, e.g., using an approach described above (e.g., vacuum chucking or ESC). The central axis of the semiconductor substrate 210 may overlap with the central axis of chuck 213 when the substrate 210 is properly aligned. In some implementations, the alignment sensor 215 may use one or more optical sensors (e.g., laser) or visual sensors for imaging (e.g., camera) for the aforementioned positioning sensing or to measure wafer eccentricity. The alignment sensor 215 may be used to sense the location of the wafer notch, and this information may be used to account for different process conditions and/or wafer positioning that may be needed in the proximity of the notch to get desired etch results.

Additional details follow regarding the relevant systems and components outlined above.

FIG. 2B illustrates an expanded, vertical cross-sectional view of a nozzle of a plasma source 208 that may be used in the system 200, in some implementations. Plasma source 208 may be an example of the plasma source 108. The plasma source 208 may include a first electrode 233 defined in approximately in the center of the nozzle. A dielectric material 238 may be disposed to surround the first electrode 233 so that a first channel 235 is defined between the first electrode 233 and the dielectric material 238. The first channel 235 may be connected to a first gas source (FIG. 1B) through a first inlet 231 defined at a first end, and to a first opening 242 at a second end defined proximate to the top of the nozzle. The first channel 235 may be configured to receive a first gas from the first gas source through the first inlet 231. A second electrode 234 may be embedded within the dielectric material 238 and surround the first electrode 233. The dielectric material 238 may act as a barrier to metal surfaces so as to prevent arcing and metal contamination when RF power is applied.

In some implementations, the first gas may be an etchant gas. In some cases, the first gas may be a reactant gas or a mixture of gases, including, e.g., oxygen-based, fluorine-based, hydrogen-based, chlorine-based chemistries, or another etchant precursor and/or an inert carrier gas such as argon, neon, or helium. The inert gas may be used to carry plasma radicals of the etchant through the first opening 242. It should be noted that the aforementioned examples of gases are provided as mere examples and should not be considered restrictive. Where the system 200 is used for edge bevel removal, depending on the type of films (i.e., residues) of the edge of a substrate which is being targeted for removal, the carrier gas may be any stable, inert gas such as argon, neon or helium, and the etchant gas may contain oxygen, fluorine, chlorine, or some other halogen, or hydrogen. In some cases where deposition is desired with the APPJ system, the first gas may be a mixture of a deposition gas and a carrier gas.

As noted above, the RF power may be modulated so as to vary the emission of plasma radicals as the substrate 210 spins, thereby creating a desired pattern of etching, e.g., at the front side of the substrate 210. Such modulation may be performed based on signals generated by a controller, logic, a differential drive, etc. that is coupled to the plasma source, upper electrode subassembly 202 and/or lower electrode subassembly 204.

Further, a controller or logic may further control one or any combination of the following parameters: rate of rotation of the substrate, nozzle position relative to the substrate (in, e.g., x, y and/or z-axis), and plasma parameters (such as plasma power, plasma frequency, gas flow rate, gas composition, and/or gas pressure). In some implementations, plasma power may vary between on and off. In some implementations, plasma power may vary between high and low RF power, rather than on/off. Other parameters affecting etching may include residence time of a nozzle's jet emission at any location on the wafer. Any of these parameters can impact the etching of one or more layers, e.g., at the edge or other portions of the substrate 210. These parameters may be controlled while the substrate 210 is rotated or where the nozzle is positioned with respect to the substrate 210 (including in the X-Y-Z space, radially, and azimuthally). In some implementations where multiple nozzles are used or included in the subassembly (e.g., upper electrode subassembly 202), each of the multiple nozzles may be separately controlled.

The dielectric material 238 disposed within the nozzle may further define a second channel 236 between the dielectric material 238 and an outer wall of the nozzle 239. The second channel 236 may be coupled to a second gas source (FIG. 1B) through a second inlet 232 defined at a first end, to receive a second gas, and a second opening 243 is defined at a second end defined at the bottom of the nozzle. The second opening 243 may be defined adjacent to and surround the first opening 242. The second opening 243 may be a single opening or a plurality of openings that surround the first opening 242 (two are depicted in FIG. 2B). The second gas may be an inert gas, such as argon, neon, or helium. The second channel 236 may create a separate gas path for the second gas, and the second opening 243 in the top of the nozzle may direct the second gas to flow up without perturbing the plasma radicals flowing through the first opening 242. The second gas exiting the second opening 243 may act as a shield for the plasma radicals mixed with the carrier gas exiting the first opening 242 by encircling the mixture of plasma radicals and the carrier gas.

It will be appreciated that an additional third inlet or channel (not shown) proximate to the first inlet 231 and/or the second inlet 232 may supply a third gas such as a purge gas and/or aerostatic bearing gas through a third opening (not shown). Third channel 137 of FIG. 1B may be an example of the third inlet or channel. In some implementations, the third gas may be supplied with sufficient force to keep plasma radicals directed away from the center of the substrate 210 and toward the substrate edge and to sufficiently expose the substrate edge to plasma radicals. In some cases, the purge gas and aerostatic bearing gas may be supplied through separate third and fourth inlets and openings. Further inlets and openings may be present in other configurations.

Referring again to FIG. 2B, in some implementations, the second electrode 234 embedded in the dielectric material 238 may be oriented in parallel orientation to the first electrode 233 disposed approximately in the center of the nozzle. In some alternate implementations, the second electrode 234 embedded in the dielectric material 238 may be oriented perpendicular to the first electrode 233, at least in part. In yet alternate implementations, the second electrode 234 may be shaped to follow a contour of the dielectric material 238 and may be oriented so as to be parallel to the first electrode 233. Irrespective of the orientation, the second electrode 234 may be disposed at a pre-defined distance from the first electrode 233, wherein the pre-defined distance may be determined to enable generation of plasma of the first gas received in the first channel 235. In some implementations, the first electrode 233 may be made of metal. In some implementations, the first electrode 233 and the second electrode 234 may be made of same material. In some implementations, the first electrode 233 may be made of different material than the second electrode 234. The material used for the second electrode 234 may be chosen so as to withstand high temperatures. In some approaches, the material used for the second electrode 234 may be chosen to have a coefficient of thermal expansion (CTE) that matches the CTE of the dielectric material 238 in which the second electrode 234 is embedded. In some approaches, the first and the second electrodes 233, 234 may be made of any one of tungsten, molybdenum, iridium, rhenium, or platinum, and the dielectric material 238 may be made of any one of aluminum nitride, aluminum oxynitride, silicon nitride, aluminum oxide, or yttrium oxide. In some implementations, the dielectric material 238 and/or the first electrode 233 may be cooled using one or more cooling elements (not shown). In some cases, the cooling element may be disposed in a region that is proximate to the second electrode 234.

In some implementations, the first electrode 233 disposed proximate to the center of the nozzle may be coupled to the aforementioned RF power source, and the second electrode 234 may be grounded via a match network. In some other implementations, the first electrode 233 may be grounded and the second electrode 234 may be coupled to the RF power source via a match network. In yet other implementations, the first electrode 233 and the second electrode 234 may be coupled to the RF power source via a match network, and neither the first electrode 233 nor the second electrode 234 may be grounded.

In some configurations, a differential voltage may be applied to the first electrode 233 and the second electrode 234. As an illustrative example, for an input voltage of 2 volts (V), the voltage applied to the first electrode will be +1 V and the voltage applied to the second electrode will be −1 V (i.e., each electrode may be provided with one half of the input voltage). In some instances, a differential drive (not shown) may be coupled to the RF power source and used to switch the RF power input between the two electrodes (first electrode 233, second electrode 234). In some implementations, the differential drive may be an isolation transformer with secondary windings used to provide the differential voltage.

The topology of the nozzle may be defined so as to supply high density plasma radicals to the substrate 210 in order to achieve high-precision etching (or deposition in certain cases). In some example implementations, the flow rate of the reactant gas in the first gas may be defined to be between about 100 standard cubic centimeters per minute (sccm) and about 300 sccm, and the flow rate for the carrier gas flow may be defined to be between about 1,000 sccm and about 30,000 sccm. In some embodiments, the pressure of the plasma generated in a region between the upper and lower electrode subassemblies may be above a threshold, e.g., at least 200 torrs (Torr). In some implementations, the plasma pressure may be about 760 Torr (atmospheric). In some implementations, plasma pressure may be some other fraction of atmospheric.

The topology of the nozzle may provide an efficient and effective way of processing the substrate 210 using a simple process chamber that includes minimal hardware. The plasma can be generated remotely and provided to the edge or other portions of the substrate 210. In addition to the first and the second gas being applied to the substrate 210, a third gas may also be provided from a third channel defined adjacent to the nozzle. The third gas may act as a gas curtain pushing the first gas enveloped in the second gas away from the center of the wafer so as provide focused application of the plasma radicals, whether at the wafer edge or at a defined radius from the center. The simple design may allow the process chamber to be kept lightweight and small, enabling the process chamber to be stacked on other existing modules (e.g., loadlock), leaving no additional footprints.

In some implementations, there may be ‘n’ number of nozzles (where ‘n’ is an integer) within a housing for the nozzle, at least some of the n nozzles providing the plasma radicals simultaneously to cover a larger area of the substrate 210 or its edge. In some implementations, the nozzle housing may include 3 or 5 or 7 or 9 nozzles disposed proximate to one another. In some implementations, the ‘n’ nozzles may be disposed along an arc defined in the nozzle housing. The arc may be defined to match the curvature of the substrate edge. In some implementations, the ‘n’ nozzles may be disposed in a substantially linear fashion rather than an arc that matches the curvature of the substrate edge. In some cases the linear nozzles may be spread in a radial direction such that the nozzles may enable etching at different radial positions along the substrate. Although various implementations have been described herein with reference to the system 200 using a nozzle, the implementations are not limited to nozzle operation, and other non-nozzle tools or parts may also be engaged for processing the substrate 210.

In certain embodiments, the housing for the nozzle and/or the nozzle(s) themselves may be configured to actuate in the z-axis (e.g., vertically) and/or radially depending on the distance to a portion of the semiconductor substrate 210 such as the edge thereof. For example, the housing may actuate within the upper electrode subassembly 202 and/or the nozzle(s) may actuate within the housing. The distance to the portion of the semiconductor substrate 210 may be measured using, e.g., one or more optical sensors (e.g., laser). Based on any variation that exists in the distance between the housing or the nozzle to the semiconductor substrate 210 (which may occur because of unevenness, bow, eccentricity, etc. of the substrate), the housing or the nozzle(s) may be actuated (e.g., by a controller) correspondingly by the measured distance, thereby keeping the distance constant.

FIG. 2C is a cross-sectional diagram showing the upper electrode subassembly 202, semiconductor substrate 210 (e.g., wafer), and lower electrode subassembly 204, according to some embodiments. As can be seen, the wafer is positioned (e.g., inserted) between surfaces of the upper and lower electrode subassemblies 202, 204, and the edge of the semiconductor substrate 210 (wafer edge) is placed below a plasma source 208. Plasma source 208 may be an example of the plasma source 108.

The plasma source 208 may generate radicals. In some configurations, the generated radicals may be transported to the wafer edge. Radical generation may involve application of RF power at the upper electrode subassembly 202 only. This approach may be referred to as an “indirect” plasma generation. In some configurations, however, the radicals may be generated directly on the edge of the semiconductor substrate 210, e.g., via application of RF power with both the upper and lower electrode subassemblies. This approach may be referred to as a “direct” plasma generation.

FIG. 2D illustrates indirect plasma generation and transportation, wherein RF power may be applied to the upper electrode subassembly 202 (more specifically, to an upper electrode 203) so that radicals are generated within the plasma source 208. In some embodiments, an inductively coupled plasma (ICP) source may be used, which is a type of plasma source in which the energy is supplied by electric currents which are produced by electromagnetic induction, that is, by time-varying magnetic fields. The plasma radicals are generated remotely from the material to be processed (e.g., layers or film on semiconductor substrate 210). The generated radicals may then be emitted from the plasma source 208 and transported with carrier gas via a nozzle of the plasma source 208. Portions of a semiconductor substrate 210 (e.g., wafer edge) may be processed (e.g., etched) using the radicals that are transported there.

FIG. 2E illustrates direct plasma generation, wherein RF power may be applied to the upper electrode subassembly 202 (upper electrode 203) and the lower electrode subassembly 204 (a lower electrode 205) so that radicals are generated directly on portions of the semiconductor substrate 210 (e.g., wafer edge). In some embodiments, a capacitively coupled plasma (CCP) source may be used. Since etchants are generated directly on the wafer edge, transportation does not occur, advantageously reducing losses in radicals, e.g., via recombination 221 of radicals (e.g., O+O₂→O₃) as shown in FIG. 2F, and thereby increasing etch. Such recombination and losses may still occur in indirect plasma generation and transportation, specifically during transportation, since radical oxygen atoms may react with molecular oxygen.

As illustrated in FIG. 2F, examples of factors may be involved in processing a wafer edge using the plasma source 208 include: (1) radical generation, (2) transportation of radicals, and (3) surface reaction. Radical generation may include breakdown of gas species such as molecular oxygen (O₂→O+O).

Factors influencing radical generation may include O₂ concentration (including in carrier gas), plasma density and electron temperature, and carrier gas used. In some implementations, O₂ concentration may be less than 10% in the carrier gas. ICP in high pressure may be used to create optimum plasma density and electron temperature. The gas pressure in the reactor can be atmospheric (about 760 Torr), or it can be lower than atmosphere, i.e., a fraction of atmospheric (e.g., about 200 Torr or above). Higher pressure may contribute to higher etch rate in EBR. Carrier gas may be an inert gas, e.g., helium (He), neon (Ne), or argon (Ar).

Factors influencing radical transportation may include distance to wafer, gas flow, and recombination conditions. In some implementations, a CCP source may be used, such that distance to the wafer edge is virtually none and no transportation is involved. For example, the direct plasma generation approach as described with respect to FIG. 2E may be used. A higher gas flow rate may be used (e.g., to prevent etching of areas that should not be etched). For recombination, a O₂ pressure of less than 10% in inert gas may be specified, for example.

Surface reaction may involve etching of the wafer edge. Factors influencing surface reaction may include temperature, where a higher temperature may be used to effectuate etching. Gas composition may influence etch rate as well, where higher O₂ concentration in the purge gas and/or lower O₂ concentration in the process gas was found to have a higher etch rate.

FIG. 2G illustrates a closer view of hardware configuration of material removal system 200, according to some embodiments. A semiconductor substrate 210 may be supported and secured by an aligner 212 (including, e.g., a chuck) and inserted into a gap between the upper electrode subassembly 202 and a lower electrode subassembly 204. In some embodiments, the plasma source may include a tip 250, e.g., at a nozzle of the plasma source. Tip 250 material may be chosen for high temperature performance where needed. Refractory metals such as tungsten may allow high tip temperatures. Materials for the tip may alternatively include other metals such as molybdenum, iridium, rhenium, or platinum, in some implementations. In some embodiments, the edge of the semiconductor substrate 210 may be confined at least in part by a solid object such as a confinement ledge 252. The confinement ledge 252 may be configured, positioned, and shaped such that it confines and/or at least partially prevents etchant, materials, gas, plasma, etc. from diffusing into the inner area of the wafers.

In some embodiments, the system 200, specifically the aligner 212, may further include a chuck or be configured to interact with a chuck. In some embodiments, the chuck may comprise a stem portion and a chucking portion that interfaces with the substrate 210. The stem portion may be sufficiently narrow (e.g., diameter of stem portion is significantly smaller than, e.g., less than half of, diameter of substrate 210) to accommodate movement of the chuck into the gap between the upper and lower electrode subassemblies 202, 204 such that the plasma source and the tip 250 (or in some implementations, multiple tips or nozzles) may have access to at least the edge of the substrate 210. One example diameter for the chuck may be 10 inches.

Returning to FIG. 2G, one or more process gases 254 may be provided to the plasma source. In different implementations, processes gases 254 may include reactant or etchant gases such as oxygen and carrier gases (e.g., inert gases such as helium, neon, or argon). The process gases 254 may be excited to a plasma state (e.g., via RF power application using upper and/or lower electrodes) for direct plasma generation, or indirect plasma generation and transportation. The generated plasma radicals may be confined to a vacuum or process volume 255, at least in part based on the confinement ledge 252 and other components of the system (e.g., walls present across the confinement ledge 252).

Process gases 254 may thereby be used to generate plasma at the plasma source at a certain pressure and expelled through the tip 250. In some embodiments, the plasma may be atmospheric-pressure plasma (also known as normal-pressure plasma), which has a pressure that approximately matches that of the surrounding atmosphere. In some embodiments, the plasma may have a pressure of at least about 200 Torr or at least about 300 Torr. This is in contrast to some traditional EBR applications where etchants are generated by low-pressure plasmas. However, performance limits (e.g., low etching rate, high diffusivity) of low-pressure etchants and width of the etching profile (e.g., control of etchant delivery, accuracy and location of where etchant is delivered) may be improved using higher-pressure plasma. Nonetheless, pressure of plasma may be modified depending on implementation of the system disclosed herein and its use application. In fact, adjusting the plasma pressure is easily done for a user or operator, and obviates the need to optimize or redesign the hardware configuration when an adjustment to the etching profile and etching width is desired.

In addition, one or more purge gases 256 may be provided through an opening 257 to affect the etch profile of the EBR. Examples of purge gases 256 may include different ratios of etchant and carrier gas or inert gases. In some cases, the purge gases 256 may include nitrogen or air. The upper gap 259 may be designed to be small enough to substantially suppress plasma light-up where the gap is small, but the combination of etchant and carrier gas exiting to the plasma lit-up region may contribute to the etch profile and etch rate. In some applications, the desired etch profile may transition fast from nominally no etch to fully etched film and can be optimized by the ratio of etchant and carrier gas. Purge gases 256 may be emitted throughout an upper gap 259 at the upper portion (e.g., at the front side) of the semiconductor substrate 210. The semiconductor substrate 210 being processed by the material removal system may be very close to a dielectric surface (e.g., dielectric shield 260) of the upper electrode subassembly 202 and a dielectric surface (e.g., dielectric barrier 258) of the lower electrode subassembly 204. Hence, the upper gap 259 may be very small. In some cases, the upper gap 259 may be about 3 mils (about 0.003 inches or approximately 76.2 microns). In some cases, the upper gap 259 may be about 100 microns or less (e.g., microns to tens of microns). A lower gap 261 may exist between the semiconductor substrate 210 and the lower electrode subassembly 204. In some implementations, the lower gap 261 may be of a similar size as the upper gap 259. In some implementations, the lower gap 261 may have a small (e.g., under about 10 microns) but non-zero distance.

It is desired to select a sufficiently narrow size for the upper gap 259, between the semiconductor substrate 210 and the upper electrode subassembly 202. Substantial stiffness may be provided between the semiconductor substrate 210 and the dielectric surface (e.g., dielectric shield 260) when upper aerostatic bearing gas or purge gas 256 is flowed in a small gap in the upper gap 259. The orifice of the tip 250 may be designed to have a choked flow between the outer diameter of the orifice and the small gap to the wafer. The viscous forces through the small gap may provide a pressure that balances with pressure at the orifice exit. If the size of the gap were increased, viscous forces will reduce, thereby lowering the pressure at the orifice exit, causing flow to increase. At the same time, the force between the dielectric and the substrate varies with gap and thereby a stiffness exists. The purge gas 256 may contribute to the process results by suppressing plasma from entering the upper gap 259, which may ensure that etching does not diffuse too far into inner portions of the wafer (e.g., 102-i), which can enhance reaction product density in the area around the edge of the wafer. Therefore, another consideration can be independent control of the gas flow, e.g., to configure the purge gas 256 and/or aerostatic bearing gas to supply the desired amount of gas, e.g., at a flow rate of 0.1 to 100 standard liters per minute (slm), nominally exiting into the upper gap 259 to optimize the processing of the wafer edge. The aerostatic bearing surface area, orifice array spacing, orifice diameters, and pressure are selected to produce sufficient force and stiffness, at a controlled range of gap such that the spinning substrate 210 does not contact the aerostatic bearing surfaces in the presence of out-of-plane wafer motion. Out-of-plane motion may be caused by reasons including imperfection in the aligner 212 motion, substrate 210 distortion, including distortion that is thermally induced by the plasma jet, and substrate 210 thickness variation. The upper and lower aerostatic bearings balance with equal and opposing forces that maintain the wafer at substantially constant gaps with significant stiffness. The high stiffness may cause the force of the bearing to increase rapidly with decreasing gap and thereby stabilize the positioning of the wafer to maintain substantially consistent gaps regardless of aligner 212 motion or non-flatness of the substrate 210.

In other words, the aerostatic bearing may keep the substrate 210 on a relatively fixed plane and reduce friction against hardware surfaces as the substrate rotates. As the substrate 210 rotates, chemically reactive species such as etchant generated at the upper electrode subassembly 202 may be applied to the edge or other portions of the substrate 210. For direct plasma generation, RF voltage may be applied between the upper electrode 203 and the lower electrode 205, and a plasma can be generated in a relatively small and confined region around the wafer edge (e.g., within the process volume 255). In some etching implementations, the plasma chemistry may be selected to have volatile reaction products with the film to be etched. As examples, oxygen radicals can be specific to carbon (C) or carbon-based film, while fluorine (F) radicals may be selected against molybdenum (Mo) or tungsten (W) materials for removal. Appropriate reactants may be selected to target the metal or material to be etched. For deposition, the plasma chemistry may be selected to have deposition products for plasma enhanced chemical vapor deposition (PECVD) or plasma enhanced atomic layer deposition (PEALD). Example precursors for silicon dioxide deposition include silane and tetraethoxysilane (TEOS). Deposition gas for silicon nitride may include silane, nitrogen, and ammonia as examples. An example precursor for tungsten deposition includes tungsten hexafluoride (WF₆). These examples are illustrative and do not exclude other chemistries selected for specific film compositions.

In some example operations, the distance or gap between the upper electrode subassembly 202 and the lower electrode subassembly 204 may be set to or adjusted (e.g., via z-axis movement of the electrode subassemblies and/or substrate 210 via, e.g., the chuck) so that even a bowed substrate may be received without touching the surface of the upper and lower electrode subassemblies. The loading process will be described in more detail with respect to FIGS. 4A-4D.

In some implementations, a plasma jet or plasma jet emitter of the nozzle may be rasterized over the surface of the substrate 210. Multiple nozzles (e.g., an array or group of 2-10 nozzles or plasma jets) may perform the rasterization. In some variants, the multiple nozzles may be in a fixed position with respect to one another, and in some cases, multiple plasma jet emitters may be disposed within a given nozzle.

In some implementations, the material removal system 200 may include an exhaust (not shown) to promptly remove plasma radicals and residues released from the substrate 210 and/or its edge during or after EBR operations performed with the system 200. Prompt removal of the residues and radicals ensures that the residues do not contaminate the substrate surface and that the radicals do not damage any formed devices present on the substrate surface (e.g., on the frontside).

In some implementations, upper and lower electrodes may be vertically offset and/or horizontally offset from each other such that they are not on the same vertical axis. In such cases, electric field lines may be forced to pass through the edge region of the semiconductor substrate 210 processing (e.g., etching) may be desired.

Referring now to FIG. 2H, a cross-sectional view of the plasma source 208 with a confinement ledge 252 is illustrated. In some embodiments, as alluded to above, the confinement ledge 252 may be an additional physical feature that may be part of (e.g., unitary) the upper electrode subassembly 202 or otherwise incorporated with the system hardware. In some configurations, the confinement ledge 252 may be associated with (e.g., adjacent or proximate to) the plasma source 208. In some cases, the confinement ledge 252 may be brought out to define an exclusion region on the semiconductor substrate 210 where plasma may be substantially suppressed under the confinement ledge 252.

In some implementations, as shown in FIG. 2I, an extra confinement ledge 253 may be present. Similar to confinement ledge 252, the extra confinement ledge 253 may be configured to further suppress the volume where plasma can light up. For example, confinement ledge 253 may confine and/or at least partially prevent etchant, materials, gas, plasma, etc. from diffusing out of process volume 255. Allowing plasma in a localized region (e.g., process volume 255) where the edge of the semiconductor substrate 210 is while suppressing plasma in volumes or regions 262 where it may not be useful may improve the efficiency of the plasma-generating components (e.g., plasma source 208, upper electrode subassembly 202, and/or lower electrode subassembly 202) and may prevent processing in areas that are not wanted. The small gaps 259 that allow aerostatic bearing may also enhance the effectiveness of the confinement, e.g., by providing stiffness and pressure that balances the pressure at the orifice exit of the plasma source 208, suppressing plasma generation in the upper gap 259 where processing is not desired at the inner portions of the semiconductor substrate 210, controlling the etching profile and etching width.

Ledge features such as the confinement ledge 252 and/or the extra confinement ledge 253 may prevent other atmospheric gases (e.g., nitrogen) from entering the process volume 255, further isolating the plasma that is processing the wafer edge.

Accordingly, by leveraging the various physical configurations described above, reactive species (e.g., etchant) can be substantially confined using an aerostatic bearing at a narrow gap between the wafer and the hardware (e.g., upper electrode subassembly) to process the edge of a spinning wafer. By modulating RF power, by actuating the upper and/or lower electrode subassemblies (e.g., in X-Y-Z directions), and/or by actuating the wafer (e.g., in X-Y directions), precise positioning and processing of the wafer is possible. Rapid modulation of RF power (which as noted above can be faster than wafer rotation) and/or change in emission or flow rate of generated plasma while the wafer is spinning may allow processing (e.g., etching) at desired locations, e.g., to remove unwanted materials from the wafer edge. Processing of regions other than the edge such as inner portions may be further possible based on wafer actuation (e.g., in X-Y directions to insert it deeper into the narrow gap). In some cases, deposition may be performed, e.g., on the front side of the wafer to undo an overetch or effectuate bow compensation, or on the back side of the wafer to effectuate bow compensation.

As noted above, the RF power may be modulated so as to vary the emission of plasma radicals as the substrate 210 spins, thereby creating a desired pattern of etching. Such modulation may be performed based on signals generated by a controller, logic, a differential drive, etc. that is coupled to the plasma source 208, upper electrode, and/or lower electrode.

Moreover, as mentioned or will be mentioned elsewhere herein, the controller or logic may further control one or any combination of the following parameters: rate of rotation of the substrate, tip position relative to the substrate (in, e.g., x, y and/or z-axis), and etching rate parameters (such as plasma power, plasma frequency, gas flow rate, gas composition, and/or gas pressure).

In some operations, a parameter to control in the etching profile may include the radial position where the material removal occurs. This may result in a specified radius (or diameter) of the substrate 210. In some implementations, a substrate radius may be defined to be within a range between about 147.8 to 148.4 mm (or a difference of 0.6 mm). In some implementations, a substrate radius may be defined to be within a range between about 147.7 to 148.2 mm (or a difference of 0.5 mm). In some cases, the substrate radius may be defined to be without a range with a substantially vertical cut. This range of substrate radius may be made narrow with a precise margin (e.g., within 0.1 mm) such that the transition of the thickness of the wafer is sharp, creating a vertical cut that may help prevent a flow of radicals toward the inner portion or center of the wafer.

Some parameters may influence the manner of deposition as well. Such deposition parameters may include: plasma power (on/off; or high/low between high and low RF power, rather than on to off), plasma frequency, gas flow rate, gas composition, gas pressure, residence time of a nozzle's jet emission at any location on the wafer. Any of these deposition parameters can impact the local thickness and/or internal stress of the backside layer. These parameters may be controlled while the substrate is rotated or where the nozzle is positioned with respect to the substrate (including in the X-Y-Z space, radially, and azimuthally). In implementations where multiple nozzles are used or included in the nozzle housing, each of the multiple nozzles may be separately controlled.

### Aerostatic Bearings

FIGS. 2J-2M illustrate cross-sectional views of hardware components configured to provide aerostatic bearing while processing (e.g., etching an edge of) the semiconductor substrate 210, according to some embodiments.

FIG. 2J is a cross-sectional view of the upper electrode subassembly 202 and various ones of its components configured to provide aerostatic bearing to a semiconductor substrate, according to some embodiments. In some embodiments, the upper electrode subassembly 202 may further include a bracket 264 constructed to physically couple to an upper electrode mount 266, which in turn may be constructed to physically couple to a cooled plate 268a and/or the upper electrode 203. In some implementations, the cooled plate 268a may be configured to manage a temperature of the system 200. For example, a liquid cooled cold plate may be included in the upper electrode subassembly 202 to cool the upper electrode subassembly 202 for high-power-density operation. In an alternate example, the coolant may be circulated in the body of the upper electrode 203 and around the inside of the tip(s) 250 to allow higher power densities. In some implementations, the cooled plate 268a may be made of heat-dissipating material with high thermal conductivity (e.g., copper, aluminum, or other suitable material) to prevent the upper electrode 203 or other surrounding components from overheating from high-power-density operation. In some cases, the bracket 264 may act as a stabilizing component coupled to another hardware component or object, such as a stage 206, lower electrode subassembly 204, wall or other surface, or a processing chamber. Similarly, the upper electrode mount 266 may be configured to securely keep the other components of the upper electrode subassembly 202 stationary. The material for the body of upper electrode 203 may be chosen for optimized (lower) cost and heat extraction. For example, aluminum may be selected. Since the dielectric shield 260 and the dielectric barrier 258 also can have high heat loads, a ceramic with high thermal shock resistance, thermal conductivity, and electrical insulation may be selected for these dielectric parts, one example being aluminum nitride (AlN). In some example configurations, the area of heat load can also be ensured to be away from the edge of the ceramic and located in the center of an oversized diameter to mitigate tensile stress created in the ceramic part due to differential thermal expansion.

In some embodiments, such other components may include an upper aerostatic bearing gas manifold 272, at least one upper aerostatic bearing orifice 274a, an upper aerostatic bearing surface 276, and/or one or more clamping features 278. In some implementations, the upper aerostatic bearing gas manifold 272 may provide various inlet(s), path(s), and outlet(s) for upper aerostatic bearing gas 270, e.g., toward a top surface of the semiconductor substrate 210. In various implementations and applications, the upper aerostatic bearing gas 270 may be an inert gas, such as argon, neon, helium, nitrogen. In various implementations and applications, the upper aerostatic bearing gas 270 may have a ratio of carrier and etchant gas. The ratio may be selected along the gap size to control etch profile and etch rate. The upper aerostatic bearing gas 270 may be emitted through the at least one upper aerostatic bearing orifice 274a.

When the upper aerostatic bearing gas 270 is being emitted from the at least one upper aerostatic bearing orifice 274a, the semiconductor substrate 210 and the upper aerostatic bearing surface 276 may form a small upper gap 259 as discussed herein. In some configurations, the upper aerostatic bearing orifice 274a may be configured to have a choked flow (constricted to increase emission velocity) between the outer diameter of the upper aerostatic bearing orifice 274a and the small gap 259 to the substrate 210. The viscous forces through the gap 259 may provide a pressure that balances with pressure at the orifice exit. If the gap increases, viscous forces will reduce, thereby lowering the pressure at the orifice exit, causing flow to increase. At the same time, the force between the dielectric shield 260 and the substrate 210 varies with gap, and thereby a stiffness may exist.

FIG. 2K is a cross-sectional view of the lower electrode subassembly 204 and various ones of its components configured to provide lower aerostatic bearing to a semiconductor substrate 210, according to some embodiments. In some embodiments, the lower electrode subassembly 204 may further include the bracket 264 (which may in some implementations be separate from the bracket or the portion used with the upper electrode subassembly 202) constructed to physically couple to a lower electrode mount 286, which in turn may be constructed to physically couple to a cooled plate 268b and/or the lower electrode 205. The cooled plate 268b may be similar to the cooled plate 268a, or the two cooled plates may have different sizes, shapes, composition, etc. The lower electrode mount 286 may be configured to securely keep the other components of the lower electrode subassembly 204 stationary.

In some embodiments, such other components may include a lower aerostatic bearing gas manifold 292, at least one lower aerostatic bearing orifice 294a, a lower aerostatic bearing surface 296, and/or one or more clamping features 298. In some implementations, the lower aerostatic bearing gas manifold 292 may provide various inlet(s), path(s), and outlet(s) for lower aerostatic bearing gas 290, e.g., toward a bottom surface of the semiconductor substrate 210. In various implementations and applications, the lower aerostatic bearing gas 290 may be an inert gas, such as argon, neon, helium, nitrogen. In various implementations and applications, the lower aerostatic bearing gas 290 may have a ratio of carrier and etchant gas. The ratio may be selected along the gap size to control etch profile and etch rate with the most significant impact toward the bottom of the bevel and the backside of the semiconductor substrate 210. The lower aerostatic bearing gas 290 may be emitted through the at least one lower aerostatic bearing orifice 294a.

When the lower aerostatic bearing gas 290 is being emitted from the at least one lower aerostatic bearing orifice 294a, the semiconductor substrate 210 and the lower aerostatic bearing surface 296 may form a small lower gap 261 as discussed herein. In some configurations, the lower aerostatic bearing orifice 294a may be configured to have a choked flow between the outer diameter of the lower aerostatic bearing orifice 294a and the small gap 261 to the substrate 210. The force between the dielectric barrier 258 and the substrate 210 varies with gap, and thereby a stiffness may exist. In some embodiments, the stiffness created by the upper aerostatic bearing surface 276 and the substrate 210 and the stiffness created by the lower aerostatic bearing surface 296 and the substrate 210 may be substantially equal.

Essentially, the components of the upper and lower electrode subassemblies 202, 204 may parallel one another and be mirrored in many ways. Moreover, the opposite positioning of the upper and lower electrodes 203, 205 can enable direct plasma generation, e.g., according to FIG. 2E. In some implementations, the entire source subassembly 201 may be aligned to the edge of the semiconductor substrate 210 using mechanical adjustments. Both upper and lower electrode subassemblies 202, 204 may use the respective upper and/or lower electrode mounts 266, 286 with adjustability and compliance to establish high parallelism between upper and lower aerostatic bearing surfaces 276, 296 and the semiconductor substrate 210 when aerostatic bearing gas is flowing. The motorized stage 206 may be configured to move, e.g., the lower electrode subassembly 204 with precision to control the total gap necessary to clamp the semiconductor substrate 210 with small gaps 259, 261 between the wafer and the aerostatic bearing surfaces 276, 296

However, there may be variations in the positioning and alignment in certain components of the upper and lower electrode subassemblies 202, 204. For example, the upper and lower electrodes 203, 205 may be offset by a prescribed amount, as mentioned above. That is, in some configurations, they may not be along the same axis. The upper and/or lower electrodes 203, 205 may have tip-like features (e.g., tips 250, 280) to provide a favorable electrical field profile for generation of a high-power-density plasma. The horizontal offset between the tips 250, 280 as well as the vertical offset may be process-tuning knobs for tailoring the etch (or deposition) rate around the edge of the substrate 210. Using the direct plasma generation may also increase the etch rate for reasons discussed elsewhere herein. In some configurations, away from the tips 250, 280, the body of the respective electrodes may have a larger cross section, which can add heat capacity and conduction to surfaces where heat may be extracted.

FIG. 2L is a closer cross-sectional view of aerostatic bearing occurs with respect to the semiconductor substrate 210. In some configurations, an upper aerostatic bearing gas path 271 may be structured to provide a conduit for the upper aerostatic bearing gas 270 to flow from a source (not shown) of the gas toward the substrate 210. In some cases, an upper aerostatic bearing seal 273 and a lower aerostatic bearing seal 293 may be implemented to ensure that all of the aerostatic bearing gas flow to the substrate 210 and maintain a desired pressure without leakage. Depending on the implementation, the upper aerostatic bearing gas path 271 may split into more than one orifice, such as by using an upper aerostatic bearing orifice array 274 having three orifices in the illustrated embodiment in FIG. 2L, where orifice 274a may be one of them. Similarly, the lower aerostatic bearing gas path 291 may be split into multiple orifices as shown in FIG. 2L, where orifice 294a may be one of them.

Depending on the desired implementation, modifying the geometry, diameter, and number of orifices, as well as the width and length of upper and lower aerostatic bearing pads 277, 297 may change the load capacity, stiffness, amount of wafer flattening, and gas flow rate properties associated with the aerostatic bearings. The supplied gas pressure may also be a factor that affects these properties. For example, the diameter of the orifices may be on the order of 50 microns to hundreds of microns when the number of orifices is small (e.g., fewer than 10). However, if many orifices are created, e.g., by using a porous medium, the effective size of the orifice may be on the scale of microns for example. The supplied gas pressure may have a strong effect on the ultimate load capacity, gas consumption, and the stiffness of the aerostatic bearing. Examples of gas pressures supplied include 50 to 150 pounds per square gauge (PSIG). The areas of the aerostatic bearing pads 277 whether rectangular, circular, or otherwise may be on the order of, e.g., 10 cm². However, other example ranges of aerostatic bearing pad 277 areas can range from 1 cm² or less, to many tens of cm². Applications can take into account wafer flatness, thermally induced deflections, and/or plasma confinement due to gap and gas flow to achieve a bearing that produces the desired process outcome with minimized gas consumption or costs. As depicted in FIG. 2M, aerostatic bearing pads refer to the areas or portions of the upper and lower aerostatic bearing surfaces 276, 296 that provide the aerostatic bearing. In some embodiments, the width and length of the upper and lower aerostatic bearing pads 277, 297 may be substantially matched and substantially equal to avoid inducing non-flatness to the substrate 210 at least in the region or width of the aerostatic bearing pads 277, 297.

In alternate implementations, usage of orifices for aerostatic bearing gas may include the use of porous media for aerostatic bearing pad areas instead of discrete orifices, such as the three-orifice arrays 274, 294 illustrated. The material of the porous media may be chosen to be compatible with the process, and to have an adequate fraction of pores open through its volume. Porous ceramics may be chosen, e.g., those containing aluminum nitride, aluminum oxynitride, silicon nitride, aluminum oxide, or yttrium oxide.

According to configuration, the area of the upper and lower aerostatic bearing surfaces 276, 296, spacing of the orifice arrays 274, 294 (which may include the upper aerostatic bearing orifice 274a and the lower aerostatic bearing orifice 294a), diameter of each orifice 274a, 294a, and pressure and/or composition of the upper and lower aerostatic bearing gases 270, 290 can be selected to produce sufficient force and stiffness (e.g., selected according to example values and ranges discussed above), at a controlled range of gap such that the spinning substrate does not contact the aerostatic bearing surfaces (e.g., upper aerostatic bearing surface 276, lower aerostatic bearing surface 296) in the presence of out-of-plane wafer motion. Causes of out-of-plane motion may include imperfection in the aligner 212 motion, substrate distortion (including, e.g., bow or wafer distortion that is thermally induced by the plasma), and substrate thickness variation. In the disclosed embodiments, the upper and lower aerostatic bearings may balance with substantially equal and opposing forces that maintain the wafer at substantially constant gaps with significant stiffness. In some embodiments, the stiffness created by the upper aerostatic bearing surface 276 and the substrate 210 and the stiffness created by the lower aerostatic bearing surface 296 and the substrate 210 may thus be substantially equal. Advantageously, the opposing aerostatic bearings may then keep the edge of the substrate 210 held between the aerostatic bearing surfaces 276, 296 without touching the substrate 210 regardless of source of out-of-plane motion. Both the stiffness of the air bearings and the mounting frame (e.g., comprising upper and/or lower electrode mounts 266, 286) may combine to define the total stiffness of the force versus gap.

Using the embodiments and implementations of the structural components described above, upper and lower aerostatic bearing gases 270, 290 may supplied, e.g., through upper and lower aerostatic bearing gas manifolds 272, 292, respectively. When RF voltage is applied between the upper electrode 203 and the lower electrode 205, a plasma can be generated in a relatively small and confined region around the wafer edge, e.g., the process volume 255. For etching, the plasma chemistry may be selected to have volatile reaction products with the film to be etched, such as oxygen being selected to react with carbon-based materials on the substrate. For deposition, the plasma chemistry may be selected to have deposition products for PECVD or PEALD. The aerostatic bearing gases 270, 290 exiting respective aerostatic bearing orifices (e.g., 274a, 294a) can contribute to the process results by suppressing plasma generation or migration in the small gap between the aerostatic bearing surface (e.g., gap 259 between upper aerostatic bearing surface 276 and gap 261 between lower aerostatic bearing surface 296), and can enhance reaction product density in the area around the edge of the substrate. Therefore, one consideration can be to control the aerostatic bearing to supply the desired amount of gas nominally exiting the air bearing for process optimization. Possible gas flow rate values for the aerostatic bearing gases that may be used include, e.g., 0.1 to 100 slm.

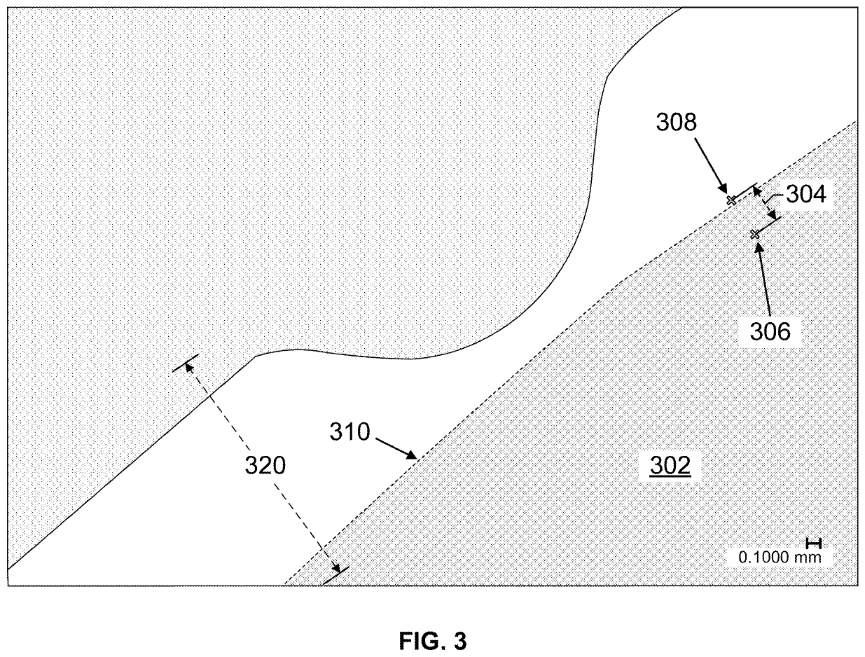

FIG. 3 is an example image depicting a semiconductor substrate 302 having at least a portion of its edge 310 processed, indicated by a processed region 320. In accordance with embodiments described herein, material may be removed at the processed region 320, and the remaining portions of the substrate 302 may still have film or other material thereon without damage to the material or the substrate. The transition between an unprocessed portion 306 and an etched portion 308, indicated by an extent 304, is quite sharp when EBR is performed using the embodiments described herein, resulting in a clean bevel at the edge of the substrate 302.

### Substrate Loading and Processing

For the material removal system described above to etch or otherwise process a semiconductor substrate, a loading process may be involved, where the substrate is received properly without damage, and aerostatic bearing keeps the substrate flattened and plasma confined to the edge of the substrate. For example, the aligner subassembly 212 shown in FIG. 2A may be used to align, secure, and position a substrate between the upper and lower electrode subassemblies 202, 204, which may then be actuated to create small gaps above and below the substrate, as discussed in detail above. Specific steps follow.

FIGS. 4A-4D illustrate some of the steps for the process of loading a semiconductor substrate for processing with the material removal system described above, according to some embodiments.

FIG. 4A illustrates a process step 401 in which a semiconductor substrate 210 may be initially loaded onto the aligner 212 and is resting on one or more pins 214. In this illustration, the substrate 210 may have already been aligned (e.g., using alignment sensor 215) to minimize wafer eccentricity, and servoed or actuated toward the upper and lower electrode subassemblies 202, 204. At this point, the upper and lower electrode subassemblies 202, 204 need not be close to the substrate 210.

FIG. 4B illustrates a process step 402 in which the chuck 213 may lift the semiconductor substrate 210 above the pins 214, e.g., via elongation. In some embodiments, the chuck 213 may secure the semiconductor substrate 210. In some implementations, the chuck 213 may be a vacuum chuck configured to operate as described elsewhere herein. In some implementations, the chuck 213 may be an ESC. While the semiconductor substrate 210 is secured by the chuck 213, the chuck 213 may move the semiconductor substrate 210 vertically with respect to the aligner 212 (e.g., z-axis) and/or horizontally (e.g., x- and/or y-axis) to a set position. The movement may bring the semiconductor substrate 210 closer toward the upper electrode subassembly 202.

FIG. 4C illustrates a process step 409 in which the aligner 212 may lift the semiconductor substrate 210 closer to the upper electrode subassembly 202. In some approaches, the upper aerostatic bearing gas may have been turned on prior to the lifting of the semiconductor substrate 210 toward the upper electrode subassembly 202 so as to prevent the semiconductor substrate 210 from contacting any surface of the upper electrode subassembly 202.

FIG. 4D illustrates a process step 411 in which at least a portion (e.g., lower electrode 205) of the lower electrode subassembly 204 may be raised toward the process position. In some approaches, the lower aerostatic bearing gas may have been turned on prior to the lower electrode subassembly 204 being raised.

It will be understood that these process steps may be done in a different order than described. Variations to this load sequence can exist. For example, process steps 401 and 402 may be changed to loading the wafer directly onto the raised pad, reversing the step of loading the substrate onto the aligner and the step of elongating the chuck above the pins. Additionally, some steps to be described below (e.g., alignment of the substrate) may be omitted in lieu of measuring the eccentricity and compensating for the eccentricity along the x-axis.

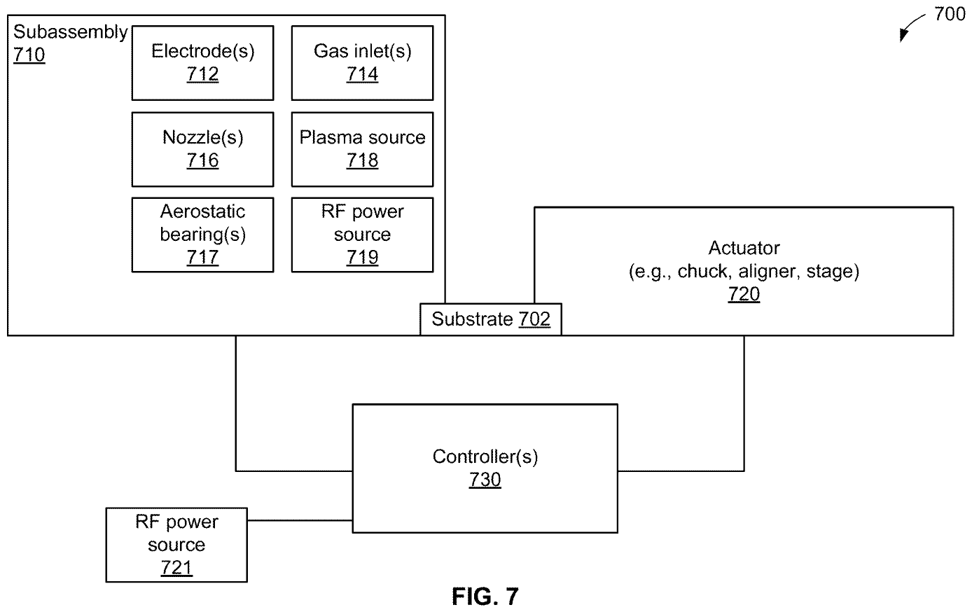

FIG. 54 is a flow diagram illustrating a method 500 of processing a semiconductor substrate, according to some embodiments. The substrate may have a frontside, the frontside having electronic device features fabricated thereon. One or more blocks of the method 500 may be performed by or caused by an apparatus or system controlled by a computing device. Such a system may include various hardware components, such as one or more electrodes, RF power supply, and/or actuator (e.g., stage, aligner) as described above. Structure for performing the functionality illustrated in one or more of the blocks shown in FIG. 5 may include hardware and/or software components of such apparatus or system, or computing device, such as, for example, a controller or a computer-readable apparatus including a storage medium storing computer-readable and/or computer-executable instructions that are configured to, when executed by a processor apparatus, cause the processor apparatus to perform the operations. Example components of the apparatus or system are discussed with respect to FIG. 7 below.

It should also be noted that the operations of the method 500 may be performed in any suitable order, not necessarily the order depicted in FIG. 5. Further, the method 500 may include additional or fewer operations than those depicted in FIG. 5 to process the semiconductor substrate.

At block 501, the method 500 may include receiving a semiconductor substrate 210 onto one or more pins 214 of an aligner 212. Aforementioned process step 401 illustrated in FIG. 4A may correspond to block 501.

At block 502, the method 500 may include moving the semiconductor substrate 210 above the one or more pins 214. In some embodiments, this may include securing the semiconductor substrate 210 using a chuck 213 (e.g., a vacuum chuck) and actuating the chuck above the pins 214 (e.g., in the z-direction). Aforementioned process step 402 illustrated in FIG. 4B may correspond to block 502.

At block 503, the method 500 may include causing the semiconductor substrate 210 to spin while measuring an eccentricity of the substrate. In some embodiments, an aligner 212 and components thereof may be used to spin the substrate (e.g., the chuck 213 may be configured to rotate while it secures the substrate) and/or measure the wafer eccentricity (using, e.g., an alignment sensor 215).

At block 504, the method 500 may optionally include orienting the semiconductor substrate 210 such that the eccentricity is aligned with an axis of the aligner 212. Chucking may be deactivated to allow the substrate 210 to be lowered onto pins 214 of the aligner 212.

At block 505, the method 500 may optionally include lowering the semiconductor substrate onto the one or more pins 214 of the aligner 212.

At block 506, the method 500 may optionally include translating the x-axis such that the spin axis of the aligner 212 is aligned with the center of the substrate 210. The aligner 212 may then lift the substrate 210 above the pins 214 and reactivate the chuck 213. This can effectively ensure the substrate 210 is centered about the spin axis of the aligner 212 where the substrate 210 can then rotate with minimized eccentricity.

If the semiconductor substrate 210 has not yet been positioned between the upper and lower electrode subassemblies 202, 204, the substrate may be moved (e.g., in x- and/or y-direction) to a position relative to an upper electrode 203 and a lower electrode 205. For example, the edge of the substrate 210 may be positioned directly underneath the upper electrode 203, while inner portions of the substrate 210 may be positioned above the lower electrode 205. An offset between the upper and lower electrodes 203, 205 such that they are not on the same vertical axis may exist in some implementations.

Alternately, positioning the semiconductor substrate 210 between the upper and lower electrode subassemblies 202, 204 may be performed at another point in the loading process, for example, during block 501 (e.g., the substrate 210 may be placed between the upper and lower electrode subassemblies 202, 204 as it is received on the pins of the aligner 212) or before block 503 (e.g., the aligner 212 may move in the x- and/or y-direction after the chuck 213 has secured the substrate 210).

At block 508, the method 500 may include activating an upper aerostatic bearing gas 270. In some embodiments, a source of the upper aerostatic bearing gas may be activated. Once turned on, the upper aerostatic bearing gas may flow through an upper aerostatic bearing gas path 271 in the upper aerostatic bearing gas manifold 272, and out of one or more upper aerostatic bearing orifices 274. In some implementations, the initial gas pressure here may be lower compared to during processing later to conserve gas supply or power.

At block 509, the method 500 may include moving the semiconductor substrate 210 to a process position. Aforementioned process step 409 illustrated in FIG. 4C may correspond to block 509. The substrate 210 may be moved very close to the upper electrode subassembly 202 (more specifically, the upper aerostatic bearing surface 276) with 100 microns or less in gap. The activation of the upper aerostatic bearing gas 270 in block 508 may be done prior to moving the substrate 210 in order to prevent the substrate 210 from touching the upper aerostatic bearing surface 276. In some cases, the semiconductor substrate 210 may additionally or alternatively be lowered rather than lifted.

At block 510, the method 500 may include activating a lower aerostatic bearing gas. In some embodiments, a source of the lower aerostatic bearing gas may be activated. Once turned on, the lower aerostatic bearing gas may flow through a lower aerostatic bearing gas path 291 in the lower aerostatic bearing gas manifold 292, and out of one or more lower aerostatic bearing orifices 294.

At block 511, the method 500 may include actuating a lower electrode subassembly 204 to a process position. In some embodiments, a stage 206 associated with the lower electrode subassembly 204 (e.g., as shown in FIGS. 2 and 2A) may be configured to actuate the lower electrode subassembly 204 in the z-direction. For example, the stage 206 may raise lower electrode subassembly 204 to the process position such that the lower aerostatic bearing surface 296 is very close to the substrate with 100 microns or less in gap. The activation of the lower aerostatic bearing gas 290 in block 510 may be done prior to actuating the lower electrode subassembly 204 in order to prevent the substrate 210 from touching the lower aerostatic bearing surface 296. In some cases, the upper electrode subassembly 202 may be lowered or raised as well.

At block 512, the method 500 may include causing the semiconductor substrate 210 to spin. In some embodiments, the chuck 213 may be configured to rotate while securing the semiconductor substrate 210. The spinning may be part of processing the substrate 210, e.g., via EBR where the edge of the substrate 210 is etched while the substrate is spinning.

To that end, at block 513, the method 500 may include generation of plasma, and processing the semiconductor substrate 210 with the plasma. In some embodiments, direct plasma generation in atmospheric pressure may be used. That is, RF power may be applied to the upper and lower electrodes 203, 205 on opposite sides of the substrate 210, which may cause plasma radicals to be generated directly on the edge of the substrate 210 as shown in FIG. 2E. In some implementations, the plasma pressure may be a fraction of atmospheric (e.g., at least about 200 Torr or at least about 300 Torr).

Advantageously, and as described elsewhere herein, the aerostatic bearing gases may be stabilizing the rotation of the substrate and providing an inert gas curtain to prevent plasma radicals from reaching portions of the substrate 210 other than its edge. Further confining the etchant plasma to the wafer edge may be a small process volume 255 in combination with one or more confinement ledges 252 and/or 253. These factors may provide a high etch rate (e.g., about or at least about 1 mm per minute) without waste via recombination 221 during transport (as may happen in the indirect plasma generation scheme of FIG. 2D where RF power is applied to one of the electrodes (e.g., upper electrode 203)).

At block 514, the method 500 may include stopping the generation of plasma, for example, when processing is complete or paused.

At block 515, the method 500 may include stopping the rotation of the semiconductor substrate, for example, when processing is complete or paused.

At block 516, the method 500 may include lowering the lower electrode subassembly 204.

At block 517, the method 500 may include lowering the semiconductor substrate 210 onto the one or more pins. In some embodiments, the chuck 213 may be deactivated to remove the vacuum from the processed substrate 210.

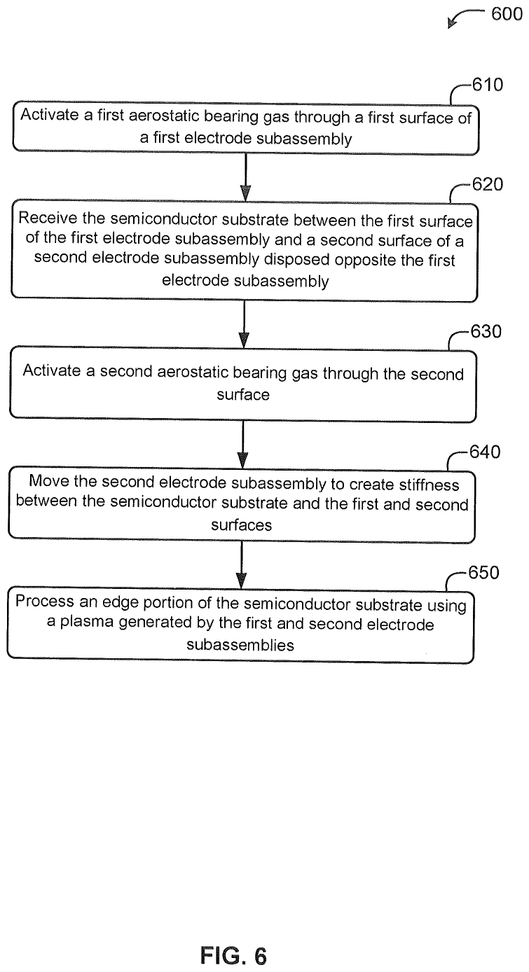

FIG. 6 is a flow diagram illustrating a method 600 of processing a semiconductor substrate, according to some embodiments. The substrate may have a frontside, the frontside having electronic device features fabricated thereon. One or more blocks of the method 600 may be performed by or caused by an apparatus or system controlled by a computing device. Such a system may include various hardware components, such as one or more electrodes, RF power supply, and/or actuator (e.g., stage, aligner) as described above. Structure for performing the functionality illustrated in one or more of the blocks shown in FIG. 6 may include hardware and/or software components of such apparatus or system, or computing device, such as, for example, a controller or a computer-readable apparatus including a storage medium storing computer-readable and/or computer-executable instructions that are configured to, when executed by a processor apparatus, cause the processor apparatus to perform the operations. Example components of the apparatus or system are discussed with respect to FIG. 7 below.

It should also be noted that the operations of the method 600 may be performed in any suitable order, not necessarily the order depicted in FIG. 6. Further, the method 600 may include additional or fewer operations than those depicted in FIG. 6 to process the semiconductor substrate.

At block 710, method 700 may include activating a first aerostatic bearing gas through a first surface of a first electrode subassembly. In some embodiments, upper electrode subassembly 202 may be an example of the first electrode subassembly, and upper aerostatic bearing surface 276 may be an example of the first surface of the first electrode subassembly. In some implementations, the first electrode subassembly may not necessarily refer to the all the components of the upper electrode subassembly 202, such as those shown in FIGS. 2J and 2L, but may refer to portions thereof, such as upper aerostatic bearing gas path 271, upper aerostatic bearing gas manifold 272, upper aerostatic bearing orifice array 274, and/or dielectric shield 260. In some embodiments, upper aerostatic bearing gas 270 may be an example of the first aerostatic bearing gas.

At block 720, method 700 may include receiving the semiconductor substrate between the first surface of the first electrode subassembly and a second surface of a second electrode subassembly disposed opposite the first electrode subassembly. In some embodiments, receiving the semiconductor substrate may occur subsequent to activating the first aerostatic bearing gas. In some embodiments, lower electrode subassembly 204 may be an example of the second electrode subassembly, and lower aerostatic bearing surface 296 may be an example of the second surface of the second electrode subassembly. In some implementations, the second electrode subassembly may not necessarily refer to the all the components of the lower electrode subassembly 204, such as those shown in FIGS. 2K and 2L, but may refer to portions thereof, such as lower aerostatic bearing gas path 291, lower aerostatic bearing gas manifold 292, lower aerostatic bearing orifice array 294, and/or dielectric barrier 258. In some embodiments, lower aerostatic bearing gas 290 may be an example of the second aerostatic bearing gas.

In some embodiments, the semiconductor substrate (e.g., semiconductor substrate 210) may be received using at least some of the process steps described with respect to FIGS. 4A-4D or some portion(s) of the method 500 described with respect to FIG. 5. For example, vacuum chucking may be used to securely hold the semiconductor substrate as it is moved in x-, y- and/or z-directions with respect to the first and second electrode subassemblies.

At block 730, method 700 may include activating a second aerostatic bearing gas through the second surface. In some embodiments, activating the second aerostatic bearing gas may occur subsequent to receiving the semiconductor substrate.

At block 740, method 700 may include moving the second electrode subassembly to create stiffness between the semiconductor substrate and the first and second surfaces. In some embodiments, a stiffness may be created between the semiconductor substrate and the first surface that is substantially equal to a stiffness created between the semiconductor substrate and the second surface, so as to, e.g., keep the semiconductor substrate flat while it is spinning. Stiffness and substantially constant gaps between the substrate and the first and second surfaces may result from upper and lower aerostatic bearings balancing with substantially equal and opposing forces (e.g., from substantially equal and opposing flow of first and second aerostatic bearing gases).

In some embodiments, moving the second electrode assembly may occur subsequent to activating the second aerostatic bearing gas. In some cases, block 740 may correspond to process step 411, where the second electrode subassembly raised toward the semiconductor substrate, while first and second aerostatic bearing gases are activated.

In some implementations, the first and/or second aerostatic bearing gases may be at a lower initial flow rate before the semiconductor substrate is sufficiently proximate to the first and second surfaces, e.g., to conserve gas supply or power. For example, a threshold distance between the semiconductor substrate and the first surface and/or a threshold distance between the semiconductor substrate and the second surface may be a condition for increasing the flow rate. In some implementations, such a threshold distance may be greater than the resulting gap between the semiconductor substrate and the first and second surfaces; e.g., the threshold may be greater than 100 microns.

At block 750, method 700 may include processing an edge portion of the semiconductor substrate using a plasma generated by the first and second electrode subassemblies. In some embodiments, processing the edge portion of the semiconductor substrate may include etching the edge portion while the semiconductor substrate is spinning. As discussed elsewhere herein, the semiconductor substrate may rotate via an aligner or other movable stage. For example, chuck 213 coupled to aligner 212 and may secure and rotate the substrate (e.g., at a rate of rotation of 60-120 per minute). In some embodiments, the plasma may be generated by applying RF power to respective electrodes of the first and second electrode subassemblies. Upper electrode 203 and lower electrode 205 may be examples of the respective electrodes, which may be positioned opposite to each other, e.g., on opposing ends of the substrate.

Direct plasma generation may be performed on the edge of the substrate itself (e.g., by igniting a process gas such as oxygen), where plasma radicals may be generated directly on the edge portion, thereby causing etching of the edge portion as the substrate spins. Aerostatic bearing provided by the first and second aerostatic bearing gases may stabilize the spinning of the substrate (e.g., cause wafer flattening). The first and second aerostatic bearing gases (in conjunction with one or more confinement ledges 252, 253 in some implementations) may further serve to prevent flow of plasma toward the center of the substrate where processing is not desired, away from the edge portion. The combination of the above features (present in the material removal system discussed herein) may advantageously result in high etch rate of the edge portion of the semiconductor substrate.

### Apparatus—Computational and Controller Embodiments

FIG. 7 illustrates a simplified block diagram of an APPJ-based material removal system or apparatus 700 as described herein, which may include at least one subassembly 710, at least one actuator 720 (e.g., chuck, aligner), and at least one controller apparatus 730 coupled to the subassembly 710 and/or the actuator 720. The subassembly 710 may include, in some embodiments, one or more sub-assemblies, examples of which include an upper subassembly and a lower subassembly having respective one or more electrodes 712 associated therewith (e.g., upper electrode(s) and lower electrode(s)). Hence, the at least one controller apparatus 730 may be configured to be coupled to the one or more electrodes 712. The at least one controller apparatus 730 may also be configured to be coupled to an external RF power source 721. The controller(s) 730 may use an internal RF power source 719 and/or the external RF power source 721 to cause power to be provided to at least components of the subassembly 710 and/or the actuator 720. The subassembly 710 may further include, in some embodiments, one or more gas inlets (or inlet lines) 714. Examples of gas inlets 714 may include a first gas inlet to provide a process gas (and/or a curtain gas) and/or a second gas inlet to provide a purge gas. The inlets 714 may be configured to deliver gas and/or plasma from a source to an outlet of the nozzle(s) 716. An axis of the nozzle(s) 716 may be at an angle relative to a plane parallel to the substrate, the angle being adjustable between orthogonal to non-orthogonal (angled). In some embodiments, the actuator 720 may include a chuck (e.g., a vacuum chuck, electrostatic clamp) and/or an aligner configured to hold, move (e.g., along X-Y-Z-R-θ), and/or rotate the substrate 702 while the substrate 702 is positioned proximate a portion of the subassembly 710 (e.g., between upper and lower electrode subassemblies with a small gap above the substrate 702 for purge gas or aerostatic bearing gas to flow). In some embodiments, the actuator 720 may include a stage (e.g., X-Y-Z) configured to actuate at least portions of the subassembly 710. For example, the aligner may hold and move the substrate 702 in X-Y-Z into a space between upper or lower assemblies movable vertically to receive the substrate 702, according to implementations described herein.

In some embodiments, the subassembly 710 may include at least one nozzle 716 that is at least partially housed by the subassembly 710 or by a nozzle housing which may in turn be at least partially housed in the subassembly 710. The nozzle 716 may be configured to direct a plasma jet into a process volume where a portion of the substrate 702 is positioned, and thereby etch and remove materials, e.g., on the edge of the substrate 702. The actuator 720 may be configured to adjustably position the substrate 702 with respect to the nozzle(s) 716 during etching, and the controller(s) 730 may be configured to control an internal RF power source 719 and/or an external RF power source 721 to provide power, e.g., to a plasma source 718, to generate plasma radicals that etch the substrate edge. The plasma source 718 may be a direct plasma source (e.g., RF power may be applied to the upper electrode and the lower electrode) or an indirect plasma source (e.g., RF power may be applied to the upper electrode).

In some embodiments, the subassembly 710 may include one or more aerostatic bearing components 717. Examples of these components may include upper aerostatic bearing gas manifold 272, upper aerostatic bearing seal 273, upper aerostatic bearing orifice array 274, upper aerostatic bearing surface 276, lower aerostatic bearing gas manifold 292, upper aerostatic bearing seal 293, lower aerostatic bearing orifice array 294, and/or lower aerostatic bearing surface 296. As discussed herein, these aerostatic bearing components 717 may be collectively configured to provide gas (e.g., upper aerostatic bearing gas 270, lower aerostatic bearing gas 290) to provide aerostatic bearings to the substrate being processed.

The apparatus 700 may be configured to implement the aforementioned methods 500 and 600 using one or more of the aforementioned components 710-730. In some embodiments, operation of the apparatus 700 may include generating and/or transporting plasma radicals from the plasma source 718 at about atmospheric pressure or a fraction thereof (e.g., at least at about 200-300 Torr), which may cause enhanced etching of a portion or edge of the substrate 702 in conjunction with purge gas and/or aerostatic bearing gas. The apparatus 700 may enable an etching rate of microns per minute of material removal around the edge of the entire edge of the wafer in consistency with throughput requirements.

In various configurations, the controller(s) 730 may be further configured to adjust one or more process conditions during an operation of the apparatus 700. The process conditions may include: a rotation rate of the substrate 702 using the actuator 720, a position and/or an angle associated with the nozzle(s) 716, RF power of the RF power source 719, a plasma power associated with the plasma jet of the nozzle(s) 716, a plasma frequency associated with the plasma jet of the nozzle(s) 716, a residence time of the plasma jet at a location on the substrate, a gas flow rate, a gas composition, a gas pressure, or any combination thereof. In some cases, the controller(s) 730 may be configured to adjust plasma power during a single rotation of the substrate 702. In some cases, the controller(s) 730 may be configured to adjust plasma power (e.g., high/low or on/off) repeatedly over numerous rotations of the substrate 702.

In some implementations, the actuator 720 may be configured to rotate the substrate 702 during EBR/etching of the substrate edge. The actuator 720 may also be configured to cause the substrate 702 to translate (e.g., x- and/or y-axis) along a plane parallel to the substrate, or along a plane orthogonal to the plane parallel to the substrate (e.g., z-axis), or cause the substrate to move radially relative to the substrate. Depending on the application, the rotation speed of the substrate may be 60-120 rotations per minute. In one example, the rate of rotation may be about 100 rotations per minute. The actuator 720 may also be configured to provide rasterized deposition of the material. The actuator 720 may also be configured to maintain a small gap between the substrate and surfaces of the subassembly 710 during etching, and wherein the gap may be between about 0 and 100 microns.

The disclosure may be described in the general context of computer code or machine-useable instructions, including computer-executable instructions such as program modules, being executed by a computer or other machine, such as a personal data assistant or other handheld device. Generally, program modules including routines, programs, objects, components, data structures, etc., refer to code that perform particular tasks or implement particular abstract data types. The disclosure may be practiced in a variety of system configurations, including hand-held devices, consumer electronics, general-purpose computers, more specialty computing devices, etc. The disclosure may also be practiced in distributed computing environments where tasks are performed by remote-processing devices that are linked through a communications network.

In some implementations, a “controller” (e.g., 190) is part of a system containing a various types of sensors as described herein. Such systems include a fabrication tool with a camera sensor. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The controller may be implemented with or coupled to analysis logic as described above. A controller may be implemented as logic such as electronics having one or more integrated circuits, memory devices, and/or software that receive instructions, issue instructions, control operation, and/or enable sensing operations.

The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the processing of one or more layers, materials, metals, oxides, silicon, silicon dioxide, surfaces, circuits, and/or dies of a wafer.

A controller may be configured to control or cause control of various components or subparts of the system or systems. The controller, depending on the processing requirements and/or the type of system, may be programmed to control any of the processes that may be used by a fabrication tool during a fabrication operation, including adjusting or maintaining the delivery of processing gases, temperature settings (e.g., heating and/or cooling) including substrate temperature and chamber wall temperature, pressure settings including vacuum settings, plasma settings, RF matching circuit settings, and substrate positional and operation settings, including substrate transfers into and out of a fabrication tool and/or load lock. Process gas parameters include the process gas composition, flow rate, temperature, and/or pressure. Of particular relevance to the disclosed embodiments, controller parameters may relate to plasma generator power, pulse rate, and/or RF frequency.

Process parameters under the control of a controller may be provided in the form of a recipe and may be entered utilizing a user interface. Signals for monitoring the process may be provided by analog and/or digital input connections of the system controller. The signals for controlling the process are output on the analog and digital output connections of the deposition apparatus.

In one example, the instructions for bringing about ignition or maintenance of a plasma are provided in the form of a process recipe. Relevant process recipes may be sequentially arranged, so that at least some instructions for the process can be executed concurrently. In some implementations, instructions for setting one or more plasma parameters may be included in a recipe preceding a plasma ignition process. For example, a first recipe may include instructions for a first time delay, instructions for setting a flow rate of an inert gas and/or a reactant gas, and instructions for setting a plasma generator to a first power set point. A second, subsequent recipe may include instructions for a second time delay and instructions for enabling the plasma generator to supply power under a defined set of parameters. A third recipe may include instructions for a third time delay and instructions for disabling the plasma generator. It will be appreciated that these recipes may be further subdivided and/or iterated in any suitable way within the scope of the present disclosure. In some deposition processes, a duration of a plasma strike may correspond to a duration of a few seconds, such as from about 3 seconds to about 15 seconds, or may involve longer durations, such as durations of up to about 30 seconds, for example. In certain implementations described herein, much shorter plasma strikes may be applied during a processing cycle. Such plasma strike durations may be on the order of less than about 50 milliseconds, with about 25 milliseconds being utilized in a specific example. As explained, plasma may be pulsed.

In some embodiments, a controller is configured to control and/or manage the operations of a RF signal generator. In certain implementations, a controller is configured to determine upper and/or lower thresholds for RF signal power to be delivered to a fabrication tool, determining actual (such as real-time) levels of RF signal power delivered to integrated circuit fabrication chamber, RF signal power activation/deactivation times, RF signal modulation duration (for, e.g., high/low or on/off states), duty cycle, operating frequency, and so forth.

As further examples, a controller may be configured to control the timing of various operations, mixing of gases, the pressure in a fabrication tool, the temperature in a fabrication tool, the temperature of a substrate or pedestal, the position of a pedestal, chuck and/or susceptor, and a number of cycles performed on one or more substrates.

A controller may comprise one or more programs or routines for controlling designed subsystems associated with a fabrication tool. Examples of such programs or routines include a substrate positioning program, a process gas control program, a pressure control program, a heater control program, and a plasma control program. A substrate positioning program may include program code for process tool components that are used to load the substrate onto a pedestal and to control the spacing between the substrate and other parts of a fabrication tool. A positioning program may include instructions for moving substrates in and out of the reaction chamber to deposit films on substrates and clean the chamber.

A process gas control program may include code for controlling gas composition and flow rates and for flowing gas into one or more process stations prior to deposition to bring about stabilization of the pressure in the process station. In some implementations, the process gas control program includes instructions for introducing gases during formation of a film on a substrate in the reaction chamber. This may include introducing gases for a different number of cycles for one or more substrates within a batch of substrates. A pressure control program may include code for controlling the pressure in the process station by regulating, for example, a throttle valve in the exhaust system of the process station, a gas flow into the process station, etc. The pressure control program may include instructions for maintaining the same pressure during the deposition of differing numbers of cycles on one or more substrates during the processing of the batch.

A heater control program may include code for controlling the current to a heating unit that is used to heat the substrate. Alternatively, the heater control program may control delivery of a heat transfer gas (such as helium) to the substrate.

In some implementations, there may be a user interface associated with a controller. The user interface may include a display screen, graphical software displays of the apparatus and/or process conditions, and user input devices such as pointing devices, keyboards, touch screens, microphones, etc.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of processing operations, examine a history of past processing operations, examine trends or performance metrics from a plurality of processing operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the processing and/or manufacturing of semiconductor wafers.

The system software may be organized in many different ways that may have different architectures. For example, various chamber component subroutines or control objects may be written to control operation of the chamber components necessary to carry out the deposition processes (and other processes, in some cases) in accordance with the disclosed embodiments.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein.

Certain features that are described in this specification in the context of separate implementations also can be implemented in combination in a single implementation. Conversely, various features that are described in the context of a single implementation also can be implemented in multiple implementations separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

1. An apparatus configured to process a semiconductor substrate, the apparatus comprising:
a first subassembly comprising a first surface, a first electrode, and a first orifice; and
a second subassembly comprising a second surface, a second electrode, and a second orifice, the second surface disposed opposite to the first surface to form a region sized to receive the semiconductor substrate between the first subassembly and the second subassembly;
wherein:
when in a first configuration, a first aerostatic bearing gas flows through the first orifice and a second aerostatic bearing gas flows through the second orifice to create a stiffness between the semiconductor substrate and the first surface and a substantially equal stiffness between the semiconductor substrate and the second surface; and
the first and second electrodes are configured to generate plasma applied to an edge portion of the semiconductor substrate while the semiconductor substrate rotates relative to the first and second subassemblies.

2. The apparatus of claim 1, wherein an aerostatic bearing is between the first surface and the semiconductor substrate based on the first aerostatic bearing gas, and an aerostatic bearing is between the second surface and the semiconductor substrate based on the second aerostatic bearing gas creates.

3. The apparatus of claim 1, wherein when in the first configuration, the first subassembly is positioned relative to the semiconductor substrate at a first distance, and the second subassembly is positioned relative to the semiconductor substrate at a second distance substantially equal to the first distance.

4. The apparatus of claim 3, wherein the first distance creates a first gap of 100 microns or less between the first surface and the semiconductor substrate, and the second distance creates a second gap of 100 microns or less between the second surface and the semiconductor substrate.

5. The apparatus of claim 3, wherein to position the first subassembly and the second subassembly in the first configuration, the first subassembly is lowered toward the semiconductor substrate using a movable stage, and the second subassembly is raised toward the semiconductor substrate using the movable stage.

6. The apparatus of claim 1, wherein:
when in the first configuration, the semiconductor substrate is received in the region between the first and second surfaces and is secured by a vacuum chuck coupled to a movable stage; and
an axis of the semiconductor substrate overlaps with an axis of the vacuum chuck.

7. The apparatus of claim 1, wherein, when in a second configuration, aerostatic bearing gas does not flow through the first orifice or the second orifice.

8. The apparatus of claim 1, wherein the first subassembly further comprises one or more ledge features configured to, when in the first configuration, confine the generated plasma to a region in which the semiconductor substrate is exposed to the plasma.

9. The apparatus of claim 8, wherein the confinement of the generated plasma within the region comprises preventing diffusion of the generated plasma into a portion of the semiconductor substrate other than the edge portion using at least the one or more ledge features and the flow of the first aerostatic bearing gas.

10. The apparatus of claim 1, wherein:
the first subassembly further comprises a plurality of first orifices, each of the plurality of first orifices configured to emit the first aerostatic bearing gas; and
the second subassembly further comprises a plurality of second orifices, each of the plurality of second orifices configured to emit the second aerostatic bearing gas.

11. The apparatus of claim 1, wherein a first flow rate of the first aerostatic bearing gas flowing through the first orifice comprises a range of 0.1 to 100 standard liters per minute (slm), and a second flow rate of the second aerostatic bearing gas flowing through the second orifice comprises 0.1 to 100 slm, the first and second flow rates being substantially equal.

12. A system configured to process a semiconductor substrate, the system comprising:
an upper electrode subassembly comprising an upper surface, an upper electrode, and an upper aerostatic bearing orifice;
a lower electrode subassembly comprising a lower surface, a lower electrode, and a lower aerostatic bearing orifice, the lower surface disposed opposite to the upper surface to form a region sized to receive the semiconductor substrate between the upper subassembly and the lower subassembly;
a stage assembly having a plurality of degrees of freedom and configured to move the semiconductor substrate to the region via at least a first degree of freedom;
wherein:
when in a first configuration, an upper aerostatic bearing gas flows through the upper aerostatic bearing orifice and a lower aerostatic bearing gas flows through the lower aerostatic bearing orifice to create a stiffness between the semiconductor substrate and the upper surface and a stiffness between the semiconductor substrate and the lower surface; and
the upper and lower electrodes are configured to generate plasma applied to an edge portion of the semiconductor substrate while the stage assembly implements a second degree of freedom on the semiconductor substrate.

13. The system of claim 12, wherein the first degree of freedom comprises translation, and the second degree of freedom comprises rotation.

14. The system of claim 12, wherein an aerostatic bearing is between the upper surface and the semiconductor substrate based on the upper aerostatic bearing gas, and an aerostatic bearing is between the lower surface and the semiconductor substrate based on the lower aerostatic bearing gas.

15. The system of claim 12, wherein when in the first configuration, the upper electrode subassembly is positioned relative to the semiconductor substrate at a first distance of 100 microns or less, and the lower electrode subassembly is positioned relative to the semiconductor substrate at a second distance of 100 microns or less, the first distance being substantially equal to the second distance.

16. The system of claim 12, wherein:
the system further comprises a first movable stage coupled to the upper and lower electrode subassemblies, and a second movable stage separate from the first movable stage;
the lower electrode subassembly is configured to be raised toward the semiconductor substrate using the first movable stage; and
to receive the semiconductor substrate in the region in the first configuration, the semiconductor substrate is secured by a vacuum chuck coupled to the second movable stage.

17. A method of processing a semiconductor substrate, the method comprising:
activating a first aerostatic bearing gas through a first surface of a first electrode subassembly;
subsequent to activating the first aerostatic bearing gas, receiving the semiconductor substrate between the first surface of the first electrode subassembly and a second surface of a second electrode subassembly disposed opposite the first electrode subassembly;
subsequent to receiving the semiconductor substrate, activating a second aerostatic bearing gas through the second surface;
subsequent to activating the second aerostatic bearing gas, moving the second electrode subassembly to create stiffness between the semiconductor substrate and the first and second surfaces; and
processing an edge portion of the semiconductor substrate using a plasma generated by the first and second electrode subassemblies.

18. The method of claim 17, wherein:
the first electrode subassembly comprises a first electrode, and the second electrode subassembly comprises a second electrode; and
the method further comprises generating the plasma using the first and second electrodes while the semiconductor substrate is between the first surface and the second surface.

19. The method of claim 17, wherein the processing the edge portion of the semiconductor substrate comprises etching the edge portion while the semiconductor substrate is spinning.

20. The method of claim 17, wherein:
the first electrode subassembly comprises one or more ledge features configured to confine the generated plasma to a region in which the semiconductor substrate is exposed to the plasma;
the processing the edge portion of the semiconductor substrate comprises confining the generated plasma within the region using the one or more ledge features of the first electrode subassembly; and
the confining of the generated plasma within the region comprises preventing diffusion of the generated plasma into a portion of the semiconductor substrate other than the edge portion using at least the one or more ledge features and a flow of the first aerostatic bearing gas.
